(19) United States
(12) Patent Application Publication
(10) Pub. No.: US 2024/0210828 A1
(43) Pub. Date: Jun. 27, 2024

(54) PHOTOSENSITIVE COMPOSITION, TRANSFER FILM, PATTERN FORMING METHOD, METHOD FOR MANUFACTURING CIRCUIT WIRING, AND METHOD FOR MANUFACTURING TOUCH PANEL

(71) Applicant: FUJIFILM Corporation, Tokyo (JP)

(72) Inventors: Keigo YAMAGUCHI, Shizuoka (JP); Kunihiko KODAMA, Shizuoka (JP)

(73) Assignee: FUJIFILM Corporation, Tokyo (JP)

(21) Appl. No.: 18/584,952

(22) Filed: Feb. 22, 2024

Related U.S. Application Data
(63) Continuation of application No. PCT/JP2022/030955, filed on Aug. 16, 2022.

(30) Foreign Application Priority Data
Aug. 31, 2021 (JP) 2021-141575

(51) Int. Cl. G03F 7/033

(52) U.S. Cl. CPC G03F 7/033

(57) ABSTRACT

An object of the present invention is to provide a photosensitive composition which has excellent resolution, and has excellent low dielectricity of a pattern to be formed in a case of being exposed to irradiation light including light having a wavelength of 365 nm. Another object of the present invention is to provide a transfer film, a pattern forming method, a method for manufacturing a circuit wiring, and a method for manufacturing a touch panel.

The photosensitive composition of the present invention contains a compound A having a carboxy group and
a compound B having a molar absorption coefficient at a wavelength of 365 nm of more than 1,000 (cm·mol/L)⁻¹,
in which a content of the carboxy group is reduced by irradiation with an actinic ray or a radiation.

### CROSS-REFERENCE TO RELATED APPLICATIONS

This application is a Continuation of PCT International Application No. PCT/JP2022/030955 filed on Aug. 16, 2022, which claims priority under 35 U.S.C. § 119(a) to Japanese Patent Application No. 2021-141575 filed on Aug. 31, 2021. The above applications are hereby expressly incorporated by reference, in their entirety, into the present application.

### BACKGROUND OF THE INVENTION

### 1. Field of the Invention

The present invention relates to a photosensitive composition, a transfer film, a pattern forming method, a method for manufacturing a circuit wiring, and a method for manufacturing a touch panel.

In a display device provided with a touch panel such as a capacitive input device (specifically, a display device such as an organic electroluminescence (EL) display device and a liquid crystal display device), a conductive pattern such as an electrode pattern corresponding to a sensor in a visual recognition portion and a wiring line for a peripheral wiring portion and a lead-out wiring portion is provided inside the touch panel.

Generally, a photosensitive material is used for forming a patterned layer (hereinafter, also simply referred to as a “pattern”), and in particular, since the number of steps to obtain the required pattern shape is small, a method using a transfer film having a temporary support and a photosensitive layer formed of the photosensitive material. Examples of the method of forming the pattern using the transfer film include a method of exposing and developing a photosensitive layer transferred from a transfer film onto any base material through a mask having a predetermined pattern shape.

As the photosensitive material and the transfer film, for example, WO2013/084886A discloses a “photosensitive resin composition containing, on a base material, a binder polymer having a carboxyl group in which an acid value is 75 mgKOH/g or more, a photopolymerizable compound, and a photopolymerization initiator” and a “photosensitive element including a support film and a photosensitive layer consisting of the photosensitive resin composition, which is provided on the support film”.

### SUMMARY OF THE INVENTION

As a result of studying the formation of the pattern using the photosensitive resin composition (photosensitive composition) and the photosensitive element (transfer film) disclosed in WO2013/084886A, the present inventors have found that there is room to further improve resolution and further reduce a dielectric constant of the formed pattern.

Incidentally, for example, in formation of a pattern having a line width of the order of μm, an exposure treatment by an i-ray (main wavelength: 365 nm) exposure method is usually applied in many cases.

Therefore, an object of the present invention is to provide a photosensitive composition which has excellent resolution and also has excellent low dielectricity of a pattern to be formed in a case of being exposed to irradiation light including light having a wavelength of 365 nm. Another object of the present invention is to provide a transfer film, a pattern forming method, a method for manufacturing a circuit wiring, and a method for manufacturing a touch panel.

As a result of intensive studies to achieve the above-described objects, the present inventors have found that the above-described objects can be achieved by the following configurations, and have completed the present invention.
[1] A photosensitive composition comprising:
a compound A having a carboxy group; and
a compound B having a molar absorption coefficient at a wavelength of 365 nm of more than 1,000 (cm·mol/L)⁻¹,
in which a content of the carboxy group is reduced by irradiation with an actinic ray or a radiation.
[2] The photosensitive composition according to [1],
in which the molar absorption coefficient of the compound B at the wavelength of 365 nm is 3,000 (cm·mol/L)⁻¹ or more.
[3] The photosensitive composition according to [1] or [2],
in which a maximal absorption wavelength of the compound B is in a range of 300 to 400 nm.
[4] The photosensitive composition according to any one of [1] to [3],
in which the compound B is a compound having a structure in which an amount of the carboxy group included in the compound A is reduced by an exposure.
[5] The photosensitive composition according to [4],
in which the compound B is a compound having a structure capable of accepting an electron from the carboxy group included in the compound A in a photoexcited state.
[6] The photosensitive composition according to any one of [3] to [5],
in which the compound B is a compound having a structure capable of accepting an electron from the carboxy group included in the compound A in a photoexcited state, and
a total number of the structures capable of accepting the electron, which are included in the compound B, is 5 mol % or more with respect to a total number of carboxy groups included in the compound A.
[7] The photosensitive composition according to any one of [1] to [6],
in which the compound B is an aromatic compound which may have a substituent.
[8] The photosensitive composition according to any one of [1] to [7],
in which the compound B is one or more selected from the group consisting of a polycyclic aromatic ring compound and a heteroaromatic ring compound, which may have a substituent.
[9] The photosensitive composition according to any one of [1] to [8],
in which the photosensitive composition contains no compound C having a maximal absorption wavelength of 580 to 800 nm, or
in a case of containing the compound C, a content of the compound C is less than 10% by mass with respect to a content of the compound A.
[10] The photosensitive composition according to any one of [1] to [9],
in which the compound A is a polymer including one or more selected from the group consisting of a repeating unit derived from acrylic acid and a repeating unit derived from methacrylic acid.
[11] The photosensitive composition according to any one of [1] to [10],
in which the photosensitive composition contains no polymerizable compound having an ethylenically unsaturated group, or
in a case of containing the polymerizable compound, a content of the polymerizable compound is 30% by mass or less with respect to a total solid content of the composition.
[12] The photosensitive composition according to any one of [1] to [11],
in which the photosensitive composition contains no polymerizable compound having an ethylenically unsaturated group, or
in a case of containing the polymerizable compound, a content of the polymerizable compound is 0.5% by mass or less with respect to a total solid content of the composition.
[13] The photosensitive composition according to any one of [1] to [12],
in which a content of the compound B is more than 0 parts by mass and 50 parts by mass or less with respect to 100 parts by mass of a content of the compound A.
[14] The photosensitive composition according to any one of [1] to [13],
in which a content of the compound B is 10 to 50 parts by mass with respect to 100 parts by mass of a content of the compound A.
[15] The photosensitive composition according to any one of [1] to [14],
in which, in a case where the following pattern forming method A is performed on a photosensitive layer formed from the photosensitive composition to form a pattern, a film reduction amount represented by Expression (F1) is 50% or less, and
in a case where the following film forming method B is performed on the photosensitive layer formed from the photosensitive composition to form a film, a relative permittivity of the film at 28 GHz, which is measured in an environment of 25° C. and 50% RH, is 3.5 or less,

film reduction amount(%)={(thickness of photosensitive layer before exposure−thickness of protruding portion of formed pattern)/thickness of photosensitive layer before exposure}×100 Expression (F1):

### <<Pattern Forming Method A>>

the photosensitive composition is applied onto a base material such that a thickness after drying is 3.0 μm to form a coating film, the obtained coating film is dried at 100° C. for 2 minutes to form a photosensitive layer, the photosensitive layer is exposed using an ultra-high pressure mercury lamp under conditions such that an integrated exposure amount measured with a 365 nm wavelength illuminance meter is 500 mJ/cm², through a mask having a line-and-space pattern with a line size of 1 μm and a line/space of 1/1, and the exposed photosensitive layer is developed by being immersed in a 1% by mass sodium carbonate aqueous solution at a liquid temperature of 23° C. for 35 seconds, rinsed with pure water for 20 seconds, and then blown with air to remove water,

### <<Film Forming Method B>>

the photosensitive composition is applied onto a base material such that a thickness after drying is 5.0 μm to form a coating film, the obtained coating film is dried at 100° C. for 2 minutes to form a photosensitive layer, and the photosensitive layer is exposed using an ultra-high pressure mercury lamp under conditions such that an integrated exposure amount measured with a 365 nm wavelength illuminance meter is 500 mJ/cm².
[16] A transfer film comprising, in the following order:
a temporary support; and
a photosensitive layer formed from the photosensitive composition according to any one of [1] to [15].
[17] A pattern forming method comprising, in the following order:
a step of forming a photosensitive layer on a base material using the photosensitive composition according to any one of [1] to [15] or the transfer film according to [16];
a step of exposing the photosensitive layer in a patterned manner; and
a step of developing the exposed photosensitive layer with an alkali developer to form a pattern.
[18] A method for manufacturing a circuit wiring, comprising, in the following order:
a step of forming a photosensitive layer on a substrate having a conductive layer,

using the photosensitive composition according to any one of [1] to [15] or the transfer film according to [16];
a step of exposing the photosensitive layer in a patterned manner;
a step of developing the exposed photosensitive layer with an alkali developer to form a pattern;
a step of etching or plating the conductive layer in a region where the pattern is not disposed;
a step of peeling off the pattern; and
a step of, in a case of performing the plating, removing the conductive layer exposed by the step of peeling off the pattern to form a wiring pattern on the substrate.
[19] A method for manufacturing a touch panel, comprising, in the following order:
a step of forming a photosensitive layer on a substrate having a conductive layer,
using the photosensitive composition according to any one of [1] to [15] or the transfer film according to [16];
a step of exposing the photosensitive layer in a patterned manner; and
a step of developing the exposed photosensitive layer with an alkali developer to form a protective film or an insulating film of the patterned conductive layer.

According to the present invention, it is possible to provide a photosensitive composition which has excellent resolution and also has excellent low dielectricity of a pattern to be formed in a case of being exposed to irradiation light including light having a wavelength of 365 nm. In addition, it is possible to provide a transfer film, a pattern forming method, a method for manufacturing a circuit wiring, and a method for manufacturing a touch panel.

### BRIEF DESCRIPTION OF THE DRAWINGS

FIG. 1 is a schematic view showing an example of a layer configuration of a transfer film according to an embodiment.

### DESCRIPTION OF THE PREFERRED EMBODIMENTS

Hereinafter, the present invention will be described in detail.

In the present specification, a numerical range expressed using “to” means a range that includes the proceeding and succeeding numerical values of “to” as a lower limit value and an upper limit value, respectively.

In addition, regarding numerical ranges that are described stepwise in the present specification, an upper limit value or a lower limit value described in a numerical range may be replaced with an upper limit value or a lower limit value of another stepwise numerical range. In addition, regarding the numerical range described in the present specification, an upper limit value or a lower limit value described in a numerical value may be replaced with a value described in Examples.

In addition, a term “step” in the present specification includes not only an independent step but also a step that cannot be clearly distinguished from other steps, as long as the intended purpose of the step is achieved.

In the present specification, a temperature condition may be set to 25° C. unless otherwise specified. For example, unless otherwise specified, a temperature at which each of the above-described steps is performed may be 25° C.

In the present specification, “transparent” means that an average transmittance of visible light having a wavelength of 400 nm to 700 nm is 80% or more, preferably 90% or more. Therefore, for example, a “transparent resin layer” refers to a resin layer having an average transmittance of visible light having a wavelength of 400 to 700 nm is 80% or more.

In addition, the average transmittance of visible light is a value measured by using a spectrophotometer, and for example, can be measured by using a spectrophotometer U-3310 manufactured by Hitachi, Ltd.

In the present specification, “actinic ray” or “radiation” means, for example, a bright line spectrum of a mercury lamp such as g-rays, h-rays and i-rays, far ultraviolet rays typified by an excimer laser, extreme ultraviolet rays (EUV light), X-rays, electron beams (EB), or the like. In addition, in the present invention, light means the actinic ray or the radiation.

Unless otherwise specified, “exposure” in the present specification encompasses not only exposure by a mercury lamp, far ultraviolet rays typified by an excimer laser, extreme ultraviolet rays, X-rays, EUV light, or the like, but also exposure of drawing by corpuscular beams such as electron beams and ion beams.

In the present specification, a content ratio of each constitutional unit of a polymer (synonymous with each repeating unit of a polymer) is a molar ratio unless otherwise specified.

In addition, in the present specification, a refractive index is a value measured with an ellipsometer at a wavelength of 550 nm unless otherwise specified.

In the present specification, unless otherwise specified, a molecular weight in a case of a molecular weight distribution is a weight-average molecular weight.

In the present specification, a weight-average molecular weight of a resin is a weight-average molecular weight obtained by performing polystyrene conversion of a value measured by gel permeation chromatography (GPC).

In the present specification, “(meth)acrylic acid” is a concept including both acrylic acid and a methacrylic acid, “(meth)acryloyl group” is a concept including both acryloyl group and methacryloyl group, and “(meth)acrylate” has a concept including both acrylate and methacrylate.

In the present specification, a fact that a compound, a layer constituting a transfer film, or the like is “alkali-soluble” refers to that a dissolution rate obtained by the following method is 0.01 μm/sec or more.

A propylene glycol monomethyl ether acetate solution having a concentration of an object (for example, a resin) of 25% by mass is applied to a glass substrate, and then heated in an oven at 100° C. for 3 minutes to obtain a coating film of the object (thickness: 2.0 μm). The above-described coating film is immersed in a 1% by mass aqueous solution of sodium carbonate (liquid temperature: 30° C.), thereby obtaining the dissolution rate (μm/sec) of the above-described coating film.

In a case where the object is not dissolved in propylene glycol monomethyl ether acetate, the object is dissolved in an organic solvent (for example, tetrahydrofuran, toluene, or ethanol) having a boiling point of lower than 200° C., other than propylene glycol monomethyl ether acetate.

In the present specification, “water-soluble” means that the solubility in 100 g of water with a pH of 7.0 at a liquid temperature of 22° C. is 0.1 g or more. Therefore, for example, a water-soluble resin is intended to be a resin which satisfies the above-described solubility conditions.

“Solid content” of a composition means a component forming a composition layer (for example, a photosensitive layer) formed of the composition, and in a case where the composition contains a solvent (for example, organic solvent, water, and the like), the solid content means all components excluding the solvent. In addition, in a case where the components are components which form a composition layer, the components are considered to be solid contents even in a case where the components are liquid components.

In the present specification, unless otherwise specified, a thickness of a layer (film thickness) is an average thickness measured using a scanning electron microscope (SEM) for a thickness of 0.5 μm or more, and is an average thickness measured using a transmission electron microscope (TEM) for a thickness of less than 0.5 μm. The above-described average thickness is an average thickness obtained by forming a section to be measured using an ultramicrotome, measuring thicknesses of any five points, and arithmetically averaging the values.

### Photosensitive Composition

The photosensitive composition according to the embodiment of the present invention contains
a compound A having a carboxy group; and
a compound B having a molar absorption coefficient at a wavelength of 365 nm of more than 1,000 (cm·mol/L)⁻¹ (hereinafter, also referred to as “compound B”),
in which a content of the carboxy group is reduced by irradiation with an actinic ray or a radiation (hereinafter, also referred to as “exposure”).

In a case where the photosensitive composition according to the embodiment of the present invention, having the above-described configuration, is exposed to irradiation light including light having a wavelength of 365 nm, the photosensitive composition according to the embodiment of the present invention has excellent resolution and also has excellent low dielectricity of a pattern to be formed.

Detailed mechanism of the action of the photosensitive composition according to the embodiment of the present invention is not clear, but the presumed mechanism of action is as follows.

In an exposed portion of a photosensitive layer formed from the photosensitive composition according to the embodiment of the present invention, polarity changes due to reduction in the content of the carboxy group of the compound A, and thus solubility in a developer changes. That is, in the exposed portion, the solubility in an alkali developer is decreased, and the solubility in an organic solvent-based developer is increased. On the other hand, in the non-exposed portion, the solubility in the developer has not changed. As a result, it is considered that the photosensitive layer has excellent pattern formability. In a case where the developer is an alkali developer, the pattern formed from the photosensitive layer according to the present invention is a negative pattern, and in a case where the developer is an organic solvent-based developer, the pattern formed from the photosensitive layer according to the present invention is a positive pattern. The negative pattern has a suppressed content of the carboxy group to a low level by the above-described mechanism, and thus the negative pattern has excellent low dielectricity due to this. On the other hand, in the positive pattern, it is possible to reduce the content of the carboxy group by performing exposure again after the pattern formation, and as a result, it is possible to obtain a pattern having excellent low dielectricity.

In addition, in the present studies, the present inventors have found that, in comparison with the curable photosensitive composition using the polymerizable compound and the photopolymerization initiator, disclosed in WO2013/084886A, it is also clarified that it is possible to form a pattern having more excellent resolution and lower dielectricity.

This is also clear from the column of Examples described in the latter part.

Furthermore, since the photosensitive composition according to the embodiment of the present invention contains the compound B having a high molar absorption coefficient at a wavelength of 365 nm, the photosensitive composition according to the embodiment of the present invention has high photosensitivity in exposure to irradiation light including light having a wavelength of 365 nm. It is presumed that the above-described feature point of the compound B also contributes greatly to the process of reducing the carboxy group of the compound A during the exposure with irradiation light including light having a wavelength of 365 nm.

Hereinafter, the photosensitive composition will be described in detail.

In the following description, with the photosensitive composition according to the embodiment of the present invention, the fact that the resolution in a case of exposure to irradiation light including light having a wavelength of 365 nm is more excellent and/or that low dielectricity of a pattern formed by exposure to irradiation light including light having a wavelength of 365 nm is more excellent (in other words, dielectricity is further lowered) is also referred to as that “effect of the present invention is more excellent”.

The photosensitive composition contains the compound A and the compound B, and has a mechanism in which the content of the carboxy group derived from the compound A is reduced by the exposure.

A reduction rate of the content of the carboxy group derived from the compound A in the photosensitive layer is obtained by measuring an infrared (IR) spectrum of the photosensitive layer before and after the exposure and calculating a reduction rate of a peak derived from the carboxy group. The reduction rate of the content of the carboxy group is obtained by calculating a reduction rate of a peak of C═O stretching and contracting (peak in the vicinity of 1700 cm⁻¹) of the carboxy group.

In order to exhibit the above-described mechanism in which the content of the carboxy group derived from the compound A is reduced by the exposure, the compound B has a structure in which the amount of the carboxy group included in the compound A is reduced by the exposure (hereinafter, also referred to as “specific structure S0”).

The above-described specific structure S0 is a structure which exhibits an action of reducing the amount of the carboxy group included in the compound A in a case of being exposed. The specific structure S0 is preferably a structure which transitions from a ground state to an excited state by the exposure, and exhibits the action of reducing the carboxy group in the compound A in the excited state. Examples of the specific structure SO include a structure (specific structure S1 described later) capable of accepting an electron from the carboxy group included in the compound A in a photoexcited state by the exposure.

In addition, examples of embodiments of the photosensitive composition are shown below.

### Photosensitive Composition of Embodiment X-1-a1

the photosensitive composition is a photosensitive composition which contains the compound A and the compound B, and does not substantially contain a polymerizable compound and a photopolymerization initiator.

### Photosensitive Composition of Embodiment X-1-a2

the photosensitive composition is a photosensitive composition which contains the compound A and the compound B, and does not substantially contain a photopolymerization initiator.

### Photosensitive Composition of Embodiment X-1-a3

the photosensitive composition is a photosensitive composition which contains the compound A, the compound B, a polymerizable compound, and a photopolymerization initiator.

In the photosensitive composition of the embodiment X-1-a1, the “does not substantially contain a polymerizable compound” means that a content of the polymerizable compound with respect to the total solid content of the photosensitive composition may be less than 3% by mass, preferably 0% to 1% by mass, more preferably 0% to 0.5% by mass, and still more preferably 0% to 0.1% by mass.

In addition, in the photosensitive compositions of the embodiment X-1-a1 and the embodiment X-1-a2, the “does not substantially contain a photopolymerization initiator” means that a content of the photopolymerization initiator with respect to the total solid content of the photosensitive composition may be less than 0.1% by mass, preferably 0% to 0.05% by mass and more preferably 0% to 0.01% by mass.

In addition, in the photosensitive compositions of the embodiment X-1-a2 and the embodiment X-1-a3, from the viewpoint that the effect of the present invention is more excellent, the content of the polymerizable compound is preferably 30% by mass or less and more preferably 10% by mass or less with respect to the total solid content of the photosensitive composition.

Among these, from the viewpoint that the effect of the present invention is more excellent, the photosensitive composition of the embodiment X-1-a1 or the photosensitive composition of the embodiment X-1-a2 is preferable, and the photosensitive composition of the embodiment X-1-a1 is more preferable.

Examples of the mechanism by which the content of the carboxy group derived from the compound A is reduced by the exposure include a method by decarboxylation. The fact that the content of the carboxy group derived from the compound A is reduced by the decarboxylation means that the carboxy group is eliminated as CO₂, which does not include a case where the carboxy group is changed to a group other than the carboxy group by esterification or the like.

In the following, an estimation mechanism in which the content of the carboxy group derived from the compound A is reduced by the decarboxylation will be described in detail by taking, as an example, an aspect in which the compound A is polyacrylic acid and the compound B is acridine.

As shown below, a carboxy group of the polyacrylic acid and a nitrogen atom of the acridine form a hydrogen bond in the coexistence. In a case where the acridine is exposed, acceptability of the electron increases, and the electron is transferred from the carboxy group of the polyacrylic acid (step 1: photoexcitation). In a case where the carboxy group included in the polyacrylic acid transfers the electron to the acridine, the carboxy group is to be unstable and to be carbon dioxide, and is eliminated (step 2: decarboxylation reaction). After the above-described decarboxylation reaction, a radical is generated in the residue of the polyacrylic acid, and a radical reaction proceeds. The radical reaction can occur between the residues of the polyacrylic acid, between the residue of the polyacrylic acid and any polymerizable compound (monomer (M)), or with a hydrogen atom in the atmosphere (step 3: polarity conversion. crosslinking. polymerization reaction). After the radical reaction is completed, the compound B can be regenerated and contribute to the decarboxylation process of the compound A again (step 4: regeneration of compound B (catalyst)).

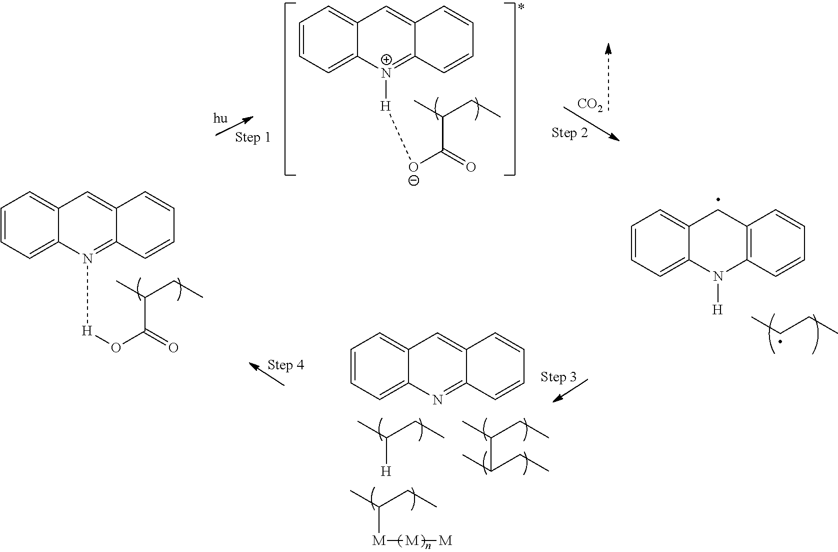

Due to the above-described mechanism, in an exposed portion of the photosensitive layer formed from the photosensitive composition, polarity changes due to reduction in the content of the carboxy group of the compound A, and thus solubility in a developer changes. That is, in the exposed portion, the solubility in an alkali developer is decreased, and the solubility in an organic solvent-based developer is increased. On the other hand, in the non-exposed portion, the solubility in the developer has not changed. As a result, it is considered that the photosensitive layer has excellent pattern formability.

### Components of Photosensitive Composition

Hereinafter, components of the photosensitive composition will be described.

### Compound A

The compound A is a compound having a carboxy group.

The compound A may be a low-molecular-weight compound or a high-molecular-weight compound (hereinafter, also referred to as a “polymer”), but is preferably a polymer. That is, the compound A is preferably a polymer having a carboxy group.

In a case where the compound A is a low-molecular-weight compound, a molecular weight of the compound A is preferably less than 5,000, more preferably 2,000 or less, still more preferably 1,000 or less, particularly preferably 500 or less, and most preferably 400 or less.

In a case where the compound A is a polymer, from the viewpoint of excellent formability of the photosensitive layer, a lower limit value of a weight-average molecular weight of the compound A is preferably 5,000 or more, more preferably 10,000 or more, and still more preferably 15,000 or more. An upper limit value thereof is not particularly limited, but from the viewpoint that adhesiveness (laminate adhesiveness) in a case of being bonded to any base material is more excellent, it is preferably 50,000 or less.

In a case where the compound A is a polymer, the polymer is preferably an alkali-soluble resin.

In addition, a part or all of carboxy groups (—COOH) included in the compound A may or may not be anionized in the photosensitive layer. In the present specification, the “carboxy group” is a concept including both an anionic carboxy group (—COO—) and a non-anionic carboxy group.

As the compound A having a carboxy group, a monomer having a carboxy group (hereinafter, also referred to as “carboxy group-containing monomer”) or a polymer having a carboxy group (hereinafter, also referred to as “carboxy group-containing polymer”) is preferable, and from the viewpoint of more excellent pattern formability and viewpoint of more excellent film-forming properties, a carboxy group-containing polymer is more preferable.

Hereinafter, the carboxy group-containing monomer and the carboxy group-containing polymer will be described.

### (Carboxy Group-Containing Monomer)

The carboxy group-containing monomer is preferably a polymerizable compound which has a carboxy group and has one or more (for example, 1 to 15) ethylenically unsaturated groups.

Examples of the ethylenically unsaturated group include a (meth)acryloyl group, a vinyl group, and a styryl group, and a (meth)acryloyl group is preferable.

From the viewpoint of more excellent film-forming properties, the carboxy group-containing monomer is preferably a bi- or higher functional monomer having a carboxy group. The bi- or higher functional monomer means a polymerizable compound having 2 or more (for example, 2 to 15) ethylenically unsaturated groups in one molecule.

The carboxy group-containing monomer may further have an acid group other than the carboxy group. Examples of the acid group other than the carboxy group include a phenolic hydroxyl group, a phosphoric acid group, and a sulfonic acid group.

The bi- or higher functional monomer having a carboxy group is not particularly limited, and can be appropriately selected from known compounds.

Examples of the bi- or higher functional monomer having a carboxy group include ARONIX (registered trademark) TO-2349 (manufactured by Toagosei Co., Ltd.), ARONIX M-520 (manufactured by Toagosei Co., Ltd.), and ARONIX M-510 (manufactured by Toagosei Co., Ltd.).

In addition, examples of the bi- or higher functional monomer having a carboxy group also include a tri- or tetra-functional polymerizable compound having a carboxy group (compound obtained by introducing a carboxy group to pentaerythritol tri- and tetra-acrylate [PETA] skeleton (acid value=80 to 120 mgKOH/g)), and a penta- or hexa-functional polymerizable compound having a carboxy group (compound obtained by introducing a carboxy group to dipentaerythritol penta- and hexa-acrylate [DPHA] skeleton (acid value=25 to 70 mgKOH/g)). In a case where the above-described tri- or higher functional monomer having a carboxy group is used, from the viewpoint of more excellent film-forming properties, it is also preferable to use the bi- or higher functional monomer having a carboxy group in combination.

Examples of the bi- or higher functional monomer having a carboxy group also include polymerizable compounds having a carboxy group, which are described in paragraphs 0025 to 0030 of JP2004-239942A. The contents of the publication are incorporated herein by reference.

### (Carboxy Group-Containing Polymer)

The carboxy group-containing polymer is usually an alkali-soluble resin.

Hereinafter, repeating units which can be included in the carboxy group-containing polymer will be described.

### <<Repeating Unit Having Carboxy Group>>

The carboxy group-containing polymer preferably has a repeating unit having a carboxy group.

Examples of the repeating unit having a carboxy group include a repeating unit represented by General Formula (A).

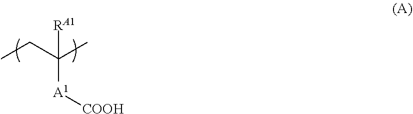

In General Formula (A), R^{A1} represents a hydrogen atom, a halogen atom, or an alkyl group.

The above-described alkyl group may be linear or branched. The number of carbon atoms in the above-described alkyl group is preferably 1 to 5 and more preferably 1.

In General Formula (A), A¹ represents a single bond or a divalent linking group.

Examples of the above-described divalent linking group include —CO—, —O—, —S—, —SO—, —SO₂—, —NR^{N}— (R^{N} is a hydrogen atom or an alkyl group having 1 to 5 carbon atoms), a hydrocarbon group (for example, an alkylene group, a cycloalkylene group, an alkenylene group, and an arylene group such as a phenylene group), and a linking group in which a plurality of these groups is linked.

Examples of a monomer from which the repeating unit having a carboxy group is derived include (meth)acrylic acid, crotonic acid, itaconic acid, maleic acid, and fumaric acid. Among these, from the viewpoint of more excellent resolution, (meth)acrylic acid is preferable. That is, the repeating unit having a carboxy group is preferably a repeating unit derived from (meth)acrylic acid, and the polymer preferably includes the repeating unit derived from (meth)acrylic acid.

A content of the repeating unit having a carboxy group in the carboxy group-containing polymer is preferably 5 to 95 mol %, more preferably 15 to 65 mol %, still more preferably 15 to 50 mol %, and particularly preferably 15 to 40 mol % with respect to all repeating units of the carboxy group-containing polymer.

The content of the repeating unit having a carboxy group in the carboxy group-containing polymer is preferably 5% to 95% by mass, more preferably 15% to 65% by mass, still more preferably 15% to 50% by mass, and particularly preferably 15% to 40% by mass with respect to the total mass of the carboxy group-containing polymer.

### <<Repeating Unit Having Aromatic Ring>>

The carboxy group-containing polymer preferably has a repeating unit having an aromatic ring, in addition to the above-described repeating unit.

As the above-described aromatic ring, an aromatic hydrocarbon ring is preferable.

Examples thereof include a repeating unit derived from (meth)acrylate having an aromatic ring, and a repeating unit derived from styrene or a polymerizable styrene derivative.

Examples of the (meth)acrylate having an aromatic ring include benzyl (meth)acrylate, phenethyl (meth)acrylate, and phenoxyethyl (meth)acrylate.

Examples of the styrene and the polymerizable styrene derivative include methylstyrene, vinyltoluene, tert-butoxystyrene, acetoxystyrene, 4-vinylbenzoic acid, styrene dimer, and styrene trimer.

As the repeating unit having an aromatic ring, for example, a repeating unit represented by Formula (C) is also preferable.

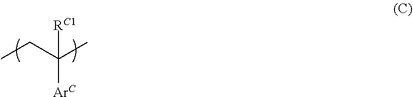

In Formula (C), R^{C1} represents a hydrogen atom, a halogen atom, or an alkyl group.

The above-described alkyl group may be linear or branched. The number of carbon atoms in the above-described alkyl group is preferably 1 to 5 and more preferably 1.

Ar^{C} represents a phenyl group or a naphthyl group. The above-described phenyl group and the above-described naphthyl group may have a substituent, and examples of the substituent include an alkyl group, an alkoxy group, an aryl group, a halogen atom, and a hydroxy group.

Ar^{C} is preferably a phenyl group.

Examples of the repeating unit having an aromatic ring include the following repeating units.

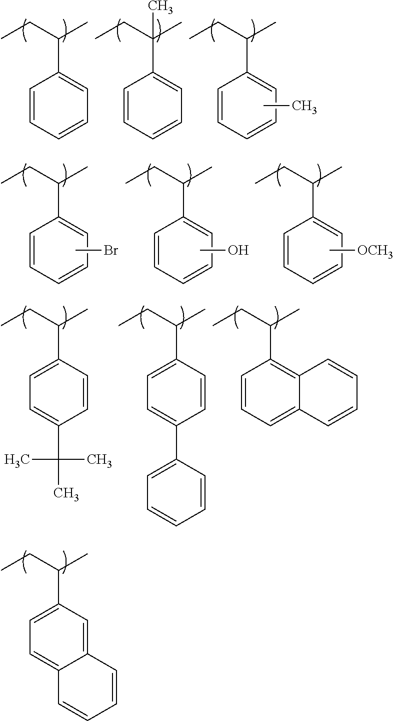

In a case where the carboxy group-containing polymer includes a repeating unit having an aromatic ring, a content of the repeating unit having an aromatic ring in the carboxy group-containing polymer is preferably 5 to 90 mol %, more preferably 15 to 85 mol %, still more preferably 30 to 80 mol %, and particularly preferably 50 to 80 mol % with respect to all repeating units of the carboxy group-containing polymer.

In a case where the carboxy group-containing polymer includes a repeating unit having an aromatic ring, the content of the repeating unit having an aromatic ring in the carboxy group-containing polymer is preferably 5% to 90% by mass, more preferably 15% to 85% by mass, still more preferably 30% to 85% by mass, and particularly preferably 50% to 80% by mass with respect to the total mass of the carboxy group-containing polymer.

### <<Repeating Unit Having Alicyclic Structure>>

The carboxy group-containing polymer also preferably has a repeating unit having an alicyclic structure, in addition to the above-described repeating units.

The alicyclic structure may be monocyclic or polycyclic. Examples of the alicyclic structure include a dicyclopentanyl ring structure, a dicyclopentenyl ring structure, an isobornyl ring structure, an adamantane ring structure, and a cyclohexyl ring structure.

Examples of a monomer from which the repeating unit having an alicyclic structure is derived include dicyclopentanyl (meth)acrylate, dicyclopentenyl (meth)acrylate, isobornyl (meth)acrylate, adamantyl (meth)acrylate, and cyclohexyl (meth)acrylate.

In a case where the carboxy group-containing polymer includes a repeating unit having an alicyclic structure, a content of the repeating unit having an alicyclic structure in the carboxy group-containing polymer is preferably 5 to 90 mol %, more preferably 15 to 85 mol %, still more preferably 30 to 80 mol %, and particularly preferably 50 to 80 mol % with respect to all repeating units of the carboxy group-containing polymer.

In a case where the carboxy group-containing polymer includes a repeating unit having an alicyclic structure, the content of the repeating unit having an alicyclic structure in the carboxy group-containing polymer is preferably 5% to 90% by mass, more preferably 15% to 85% by mass, still more preferably 30% to 85% by mass, and particularly preferably 30% to 60% by mass with respect to the total mass of the carboxy group-containing polymer.

### <<Repeating Unit Having Polymerizable Group>>

The carboxy group-containing polymer also preferably has a repeating unit having a polymerizable group, in addition to the above-described repeating units.

Examples of the polymerizable group include an ethylenically unsaturated group (for example, a (meth)acryloyl group, an allyl group, a styryl group, and the like), and a cyclic ether group (for example, an epoxy group, an oxetanyl group, and the like), and an ethylenically unsaturated group is preferable and an allyl group or a (meth)acryloyl group is more preferable.

Examples of the repeating unit having a polymerizable group include a repeating unit represented by General Formula (B).

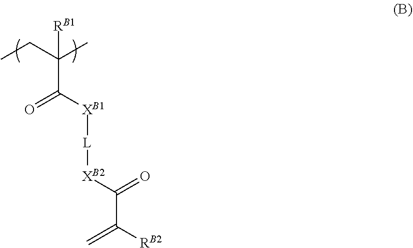

In General Formula (B), X^{B1} and X^{B2} each independently represent —O— or —NR^{N}—.

R^{N} represents a hydrogen atom or an alkyl group. The above-described alkyl group may be linear or branched, and the number of carbon atoms therein is preferably 1 to 5.

L represents an alkylene group or an arylene group. The above-described alkylene group may be linear or branched, and the number of carbon atoms therein is preferably 1 to 5. The above-described arylene group may be monocyclic or polycyclic, and the number of carbon atoms therein is preferably 6 to 15. The above-described alkylene group and arylene group may have a substituent, and the substituent is preferably, for example, an acid group.

R^{B1} and R^{B2} each independently represent a hydrogen atom or an alkyl group. The above-described alkyl group may be linear or branched. The number of carbon atoms in the above-described alkyl group is preferably 1 to 5 and more preferably 1.

In addition, the repeating unit having a polymerizable group may be a repeating unit derived from a compound having an allyl group. Examples of the above-described unit include a repeating unit derived from allyl (meth)acrylate.

In a case where the carboxy group-containing polymer includes a repeating unit having a polymerizable group, a content thereof is preferably 3 to 60 mol %, more preferably 5 to 40 mol %, and still more preferably 10 to 30 mol % with respect to all repeating units of the carboxy group-containing polymer.

In a case where the carboxy group-containing polymer includes a repeating unit having a polymerizable group, the content thereof is preferably 3% to 60% by mass, more preferably 4% to 40% by mass, and still more preferably 10% to 30% by mass with respect to the total mass of the carboxy group-containing polymer.

### <<Other Repeating Units>>

The carboxy group-containing polymer may have other repeating units in addition to the above-described repeating units.

Examples of a monomer from which the other repeating units are derived include alkyl (meth)acrylates such as methyl (meth)acrylate. An alkyl group in the alkyl (meth)acrylate is preferably linear or branched. The above-described alkyl group may further have a substituent such as a hydroxy group. The number of carbon atoms in the alkyl group is preferably 1 to 50, more preferably 1 to 10, and still more preferably 1 to 6.

In a case where the carboxy group-containing polymer includes other repeating units, a content of the other repeating units in the carboxy group-containing polymer is preferably 1 to 70 mol %, more preferably 2 to 50 mol %, and still more preferably 3 to 20 mol % with respect to all repeating units of the carboxy group-containing polymer.

In a case where the carboxy group-containing polymer includes other repeating units, a content of the other repeating units in the carboxy group-containing polymer is preferably 1% to 70% by mass, more preferably 2% to 50% by mass, and still more preferably 2% to 45% by mass with respect to the total mass of the carboxy group-containing polymer.

A content of the carboxy group-containing polymer in the compound A is preferably 75% to 100% by mass, more preferably 85% to 100% by mass, still more preferably 90% to 100% by mass, and particularly preferably 95% to 100% by mass with respect to the total mass of the compound A.

A content of the carboxy group-containing monomer in the compound A is preferably 0% to 25% by mass, more preferably 0% to 10% by mass, and still more preferably 0% to 5% by mass with respect to the total mass of the compound A.

The carboxy group-containing polymer may further have an acid group other than the carboxy group. Examples of the acid group other than the carboxy group include a phenolic hydroxyl group, a phosphoric acid group, and a sulfonic acid group.

From the viewpoint of developability, an acid value of the carboxy group-containing polymer is preferably 60 to 300 mgKOH/g, more preferably 60 to 275 mgKOH/g, and still more preferably 75 to 250 mgKOH/g.

In the present specification, the acid value of the carboxy group-containing polymer is a value measured by a titration method specified in JIS K0070 (1992).

In the photosensitive composition, a lower limit value of a content of the compound A is preferably 1% by mass or more, more preferably 15% by mass or more, still more preferably 20% by mass or more, even more preferably 30% by mass or more, particularly preferably 45% by mass or more, and most preferably 50% by mass or more with respect to the total solid content of the photosensitive composition. An upper limit value of the content of the compound A is preferably 100% by mass or less, more preferably 99% by mass or less, still more preferably 97% by mass or less, particularly preferably 95% by mass or less, and most preferably 94% by mass or less with respect to the total solid content of the photosensitive composition.

Among these, in the photosensitive composition of the embodiment X-1-a1, the content of the compound A is preferably 20% to 98% by mass, more preferably 50% to 95% by mass, still more preferably 60% to 95% by mass, and even more preferably 60% to 94% by mass with respect to the total solid content of the photosensitive composition.

### Compound B

The photosensitive composition contains the compound B.

The compound B has a molar absorption coefficient at a wavelength of 365 nm of more than 1,000 (cm·mol/L)⁻¹. From the viewpoint that the effect of the present invention is more excellent, the molar absorption coefficient of the compound B at a wavelength of 365 nm is preferably 3,000 (cm·mol/L)⁻¹ or more, and more preferably 4,500 (cm·mol/L)⁻¹ or more. The upper limit value thereof is, for example, preferably 50,000 (cm·mol/L)⁻¹ or less, more preferably 15,000 (cm·mol/L)⁻¹ or less, and still more preferably 10,000 (cm·mol/L)⁻¹ or less.

The above-described light absorption coefficient to light having a wavelength of 365 nm is a light absorption coefficient measured by dissolving the compound B in acetonitrile. In a case where the compound B is insoluble in acetonitrile, the acetonitrile may be appropriately changed to a solvent for dissolving the compound B.

In addition, from the viewpoint that the effect of the present invention is more excellent, the maximal absorption wavelength of the compound B is preferably, for example, in a range of 300 to 500 nm and more preferably in a range of 300 to 400 nm.

The above-described maximal absorption wavelength is measured by dissolving the compound B in acetonitrile. In a case where the compound B is insoluble in acetonitrile, the acetonitrile may be appropriately changed to a solvent for dissolving the compound B.

As described above, the compound B is preferably a compound having a structure (specific structure S0) in which the amount of the carboxy group included in the compound A is reduced by the exposure. The specific structure S0 is as described above.

The specific structure S0 included in the compound B may be an overall structure constituting the entire compound B or a partial structure constituting a part of the compound B.

The compound B may be a high-molecular-weight compound or a low-molecular-weight compound, and is preferably a low-molecular-weight compound.

A molecular weight of the compound B as a low-molecular-weight compound is preferably less than 5,000, more preferably less than 1,000, still more preferably 65 to 400, and particularly preferably 100 to 300.

Among these, as the specific structure S0, a structure (specific structure S1) capable of accepting an electron from the carboxy group included in the compound A in a photoexcited state is preferable. That is, the compound B is preferably a compound having the structure (specific structure S1) capable of accepting an electron from the carboxy group included in the compound A in a photoexcited state. According to the compound B, it is considered that the carboxy group included in the compound A can be eliminated (decarboxylated) as CO₂.

From the viewpoint of more excellent pattern formability, the compound B is preferably an aromatic compound.

Here, the aromatic compound is intended to be a compound having an aromatic ring.

In the compound B, the aromatic ring can be used as the above-described structure (specific structure) capable of accepting an electron from the carboxy group included in the compound A in a photoexcited state. The above-described aromatic ring may be an overall structure constituting the entire compound B or a partial structure constituting a part of the compound B.

The above-described aromatic ring of the compound B may be a monocycle or a polycycle, and the number of ring member atoms is preferably 5 to 20 and more preferably 5 to 15.

Among these, from the viewpoint that the molar absorption coefficient at a wavelength of 365 nm is higher, the above-described aromatic ring of the compound B is preferably a polycycle (polycyclic aromatic ring). That is, as a suitable aspect of the compound B, a compound including a polycyclic aromatic ring (polycyclic aromatic ring compound) is preferable.

The polycyclic aromatic ring is a structure in which a plurality of aromatic rings is fused, and it may be any one of a polycyclic aromatic hydrocarbon ring or a polycyclic aromatic heterocyclic ring. Among these, a polycyclic aromatic heterocyclic ring is preferable.

Examples of a heteroatom in the polycyclic aromatic heterocyclic ring include a nitrogen atom, an oxygen atom, and a sulfur atom, and a nitrogen atom is preferable.

In addition, the number of heteroatoms included as ring member atoms is not particularly limited, and examples thereof include 1 to 4.

The number of monocyclic aromatic rings (the number of fused rings) in the polycyclic aromatic ring is not particularly limited. For example, the number thereof is 2 or more, and from the viewpoint that the molar absorption coefficient at a wavelength of 365 nm is higher, it is preferably 3 or more. The upper limit value thereof is not particularly limited, and is, for example, 6 or less.

Among these, from the viewpoint that the effect of the present invention is more excellent, the number thereof is preferably 3. Examples of the polycyclic aromatic ring having 3 rings include an acridine ring, a benzo[f]quinoline ring, a benzo[h]quinoline ring, a phenanthridine ring (benzo[c]quinoline ring), benzo[h]isoquinoline a ring, a phenanthroline ring, and a phenazine ring.

The above-described aromatic ring of the compound B may have one or more (for example, 1 to 5) substituents, and examples of the substituent include an alkyl group, an aryl group, a halogen atom, an acyl group, an alkoxycarbonyl group, an arylcarbonyl group, a carbamoyl group, a hydroxy group, a cyano group, and a nitro group. In addition, in a case where the above-described aromatic ring has two or more substituents, a plurality of substituents may be bonded to each other to form a non-aromatic ring.

In addition, it is also preferable that the above-described aromatic ring is directly bonded to a carbonyl group to form an aromatic carbonyl group in the compound B. It is also preferable that a plurality of aromatic rings is bonded through a carbonyl group.

It is also preferable that the above-described aromatic ring is bonded to an imide group to form an aromatic imide group in the compound B. The imide group in the aromatic imide group may or may not form an imide ring together with the aromatic ring.

In a case where a plurality of aromatic rings (for example, 2 to 5 aromatic rings) forms a series of aromatic ring structures bonded with a structure selected from the group consisting of a single bond, a carbonyl group, and a multiple bond (for example, a vinylene group which may have a substituent, —C≡C—, —N═N—, and the like), the entire series of aromatic ring structures is regarded as one specific structure.

In addition, it is preferable that one or more of aromatic rings constituting the series of aromatic ring structures are the heteroaromatic rings.

In a case where the compound B is a polymer, the compound B may be a polymer in which the specific structure (for example, the above-described aromatic ring) is bonded to a polymer main chain through a single bond or a linking group.

Specific examples of the compound B include acridine, benzo[f]quinoline, benzo[h]quinoline, phenanthridine, benzo[h]isoquinoline, phenanthroline, and phenazine. In addition, the above-described compound may further have a substituent. As the above-described substituent, an alkyl group, an aryl group, a halogen atom, an acyl group, an alkoxycarbonyl group, an arylcarbonyl group, a carbamoyl group, a hydroxy group, a cyano group, or a nitro group is preferable.

The compound B may be used alone, or in combination of two or more kinds thereof.

From the viewpoint of more excellent pattern formability, a content of the compound B in the photosensitive composition is preferably 0.1% to 80% by mass, more preferably 1.0% to 60% by mass, and still more preferably 1.0% to 45% by mass with respect to the total solid content of the photosensitive composition.

Among these, in the photosensitive composition of the embodiment X-1-a1, the content of the compound B is more preferably 1.0% to 60% by mass and still more preferably 1.0% to 45% by mass with respect to the total solid content of the photosensitive composition.

From the viewpoint that the effect of the present invention is more excellent, a lower limit value of the content of the compound B with respect to 100 parts by mass of the content of the compound A is preferably more than 0 parts by mass and more preferably 10 parts by mass or more. In addition, from the viewpoint that the effect of the present invention is more excellent, an upper limit value of the content of the compound B with respect to 100 parts by mass of the content of the compound A is preferably 50 parts by mass or less.

From the viewpoint of more excellent pattern formability, the total number of the structures (specific structures) capable of accepting an electron, included in the compound B of the photosensitive composition, is preferably 1 mol % or more, more preferably 3 mol % or more, still more preferably 5 mol % or more, and particularly preferably 10 mol % or more with respect to the total number of the carboxy groups included in the compound A.

The upper limit of the total number of the structures (specific structures) capable of accepting an electron, included in the compound B, is not particularly limited, but from the viewpoint of quality of a film to be obtained, is preferably 200 mol % or less, more preferably 100 mol % or less, still more preferably 80 mol % or less, particularly preferably 70 mol % or less, and most preferably 65 mol % or less with respect to the total number of the carboxy groups included in the compound A.

### <Polymerizable Compound (Polymerizable Compound Having Ethylenically Unsaturated Group)>

The photosensitive composition may contain a polymerizable compound. The polymerizable compound is a component different from the compound A having a carboxy group, and does not include a carboxy group.

The polymerizable compound is preferably a component different from the compound A, and for example, is preferably a compound having a molecular weight (a weight-average molecular weight in a case of having a molecular weight distribution) of less than 5,000 and also preferably a polymerizable monomer.

The polymerizable compound is a polymerizable compound having 1 or more (for example, 1 to 15) ethylenically unsaturated groups in one molecule.

The polymerizable compound preferably includes a bi- or higher functional polymerizable compound.

Here, the bi- or higher functional polymerizable compound means a polymerizable compound having 2 or more (for example, 2 to 15) ethylenically unsaturated groups in one molecule.

Examples of the ethylenically unsaturated group include a (meth)acryloyl group, a vinyl group, and a styryl group, and a (meth)acryloyl group is preferable.

The polymerizable compound is preferably (meth)acrylate.

In a case where the photosensitive composition contains a polymerizable compound, the polymerizable compound is preferably one or more kinds selected from the group consisting of a bifunctional polymerizable compound and a trifunctional polymerizable compound, and it is preferable to contain a bifunctional polymerizable compound.

In a case where the photosensitive composition contains a polymerizable compound, a content of the bifunctional polymerizable compound is preferably 60% to 100% by mass, more preferably 80% to 100% by mass, and still more preferably 90% to 100% by mass with respect to the total mass of all polymerizable compounds contained in the photosensitive composition.

The bifunctional polymerizable compound is not particularly limited and can be appropriately selected from a known compound.

Examples the bifunctional polymerizable compound include tricyclodecane dimethanol di(meth)acrylate, 1,9-nonanediol di(meth)acrylate, and 1,6-hexanediol di(meth)acrylate.

More specific examples of the bifunctional polymerizable compound include tricyclodecane dimethanol diacrylate (A-DCP manufactured by Shin-Nakamura Chemical Co., Ltd.), tricyclodecane dimethanol dimethacrylate (DCP manufactured by Shin-Nakamura Chemical Co., Ltd.), 1,9-nonanediol diacrylate (A-NOD-N manufactured by Shin-Nakamura Chemical Co., Ltd.), and 1,6-hexanediol diacrylate (A-HD-N manufactured by Shin-Nakamura Chemical Co., Ltd.).

The tri- or higher functional polymerizable compound is not particularly limited and can be appropriately selected from a known compound.

Examples of the tri- or higher functional polymerizable compound include dipentacrythritol (tri/tetra/penta/hexa) (meth)acrylate, pentacrythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

Here, the “(tri/tetra/penta/hexa) (meth)acrylate” is a concept including tri(meth)acrylate, tetra(meth)acrylate, penta(meth)acrylate, and hexa(meth)acrylate, and the “(tri/tetra) (meth)acrylate” is a concept including tri(meth)acrylate and tetra(meth)acrylate.

In addition, examples of the polymerizable compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), an alkylene oxide-modified compound of a (meth)acrylate compound (KAYARAD RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., or the like), and ethoxylated glycerin triacrylate (A-GLY-9E manufactured by Shin-Nakamura Chemical Co., Ltd., or the like).

Examples of the polymerizable compound also include urethane (meth)acrylate (preferably, tri- or higher functional urethane (meth)acrylate). The lower limit of the number of functional groups is preferably 6 or more and more preferably 8 or more. The upper limit of the number of functional groups is preferably 20 or less.

Examples of the tri- or higher functional urethane (meth)acrylate include 8UX-015A (manufactured by Taisei Fine Chemical Co., Ltd.); UA-32P, U-15HA, and UA-1100H (all manufactured by Shin-Nakamura Chemical Co., Ltd.); AH-600 manufactured by KYOEISHA CHEMICAL Co., LTD.; and UA-306H, UA-306T, UA-306I, UA-510H, and UX-5000 (all manufactured by Nippon Kayaku Co., Ltd.).

A molecular weight (in a case of having a molecular weight distribution, a weight-average molecular weight) of the polymerizable compound is preferably less than 5,000, more preferably 200 to 3,000, still more preferably 250 to 2,600, and particularly preferably 280 to 2,200.

Among molecular weights of all polymerizable compounds contained in the photosensitive composition, the minimum molecular weight is preferably 250 or more and more preferably 280 or more.

The polymerizable compound may be used alone or in combination of two or more kinds thereof.

From the viewpoint that the effect of the present invention is more excellent, the photosensitive composition does not contain a polymerizable compound, or in a case of containing a polymerizable compound, a content of the polymerizable compound is preferably 30% by mass or less, more preferably 10% by mass or less, and still more preferably 5% by mass or less with respect to the total solid content of the composition.

From the viewpoint that the effect of the present invention is more excellent, it is preferable that the photosensitive composition does not substantially contain the polymerizable compound. Here, the “does not substantially contain the polymerizable compound” means that a content of the polymerizable compound with respect to the total solid content of the photosensitive composition may be less than 3% by mass, preferably 0% to 1% by mass, more preferably 0% to 0.5% by mass, and still more preferably 0% to 0.1% by mass.

### <Photopolymerization Initiator>

The photosensitive composition may contain a photopolymerization initiator.

The photopolymerization initiator may be a photoradical polymerization initiator, a photocationic polymerization initiator, or a photoanionic polymerization initiator, but a photoradical polymerization initiator is preferable.

The photopolymerization initiator is preferably at least one selected from the group consisting of an oxime ester compound (photopolymerization initiator having an oxime ester structure) and an aminoacetophenone compound (photopolymerization initiator having an aminoacetophenone structure), and more preferably includes both compounds. In a case where both compounds are contained, a content of the oxime ester compound is preferably 5% to 90% by mass, and more preferably 15% to 50% by mass with respect to the total content of the both compounds.

In addition to the above-described photopolymerization initiators, other photopolymerization initiators may be included.

Examples of other photopolymerization initiators include a hydroxyacetophenone compound, an acylphosphine oxide compound, and a bistriphenylimidazole compound.

In addition, examples the photopolymerization initiator also include polymerization initiators described in paragraphs 0031 to 0042 of JP2011-095716A and paragraphs 0064 to 0081 of JP2015-014783A.

Examples of the oxime ester compound include 1,2-octanedione, 1-[4-(phenylthio)phenyl-,2-(O-benzoyloxime)] (product name: IRGACURE OXE-01; IRGACURE series, manufactured by BASF SE), etanone, 1-[9-ethyl-6-(2-methylbenzoyl)-9H-carbazol-3-yl]-, 1-(O-acetyloxime) (product name: IRGACURE OXE-02, manufactured by BASF SE), [8-[5-(2,4,6-trimethylphenyl)-11-(2-ethylhexyl)-11H-benzo[a]carbazoyl][2-(2,2,3,3-tetrafluoro propoxy)phenyl]methanone-(O-acetyloxime) (product name: IRGACURE OXE-03, manufactured by BASF SE), 1-[4-[4-(2-benzofuranylcarbonyl)phenyl]thio]phenyl]-4-methylpentanone-1-(O-acetyloxime) (product name: IRGACURE OXE-04, manufactured by BASF SE, and product name: Lunar 6, manufactured by DKSH Management Ltd.), 1-[4-(phenylthio)phenyl]-3-cyclopentylpropan-1,2-dione-2-(O-benzoyloxime) (product name: TR-PBG-305, manufactured by Changzhou Tronly New Electronic Materials Co., Ltd.), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by Changzhou Tronly New Electronic Materials Co., Ltd.), and 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by Changzhou Tronly New Electronic Materials Co., Ltd.).

Examples of the aminoacetophenone compound include 2-(dimethylamino)-2-[(4-methylphenyl)methyl]-1-[4-(4-morpholinyl)phenyl]-1-butanone (product name: Omnirad 379EG; Omnirad series are manufactured by IGM Resins B.V.), 2-methyl-1-(4-methylthiophenyl)-2-morpholinopropan-1-one (product name: Omnirad 907), and APi-307 (1-(biphenyl-4-yl)-2-methyl-2-morpholinopropan-1-one, manufactured by Shenzhen UV-ChemTech Co., Ltd.).

Examples of the other photopolymerization initiators include 2-hydroxy-1-{4-[4-(2-hydroxy-2-methyl-propionyl)-benzyl]phenyl}-2-methyl-propan-1-one (product name: Omnirad 127), 2-benzyl-2-dimethylamino-1-(4-morpholinophenyl)-butanone-1 (product name: Omnirad 369), 2-hydroxy-2-methyl-1-phenyl-propan-1-one (product name: Omnirad 1173), 1-hydroxy-cyclohexyl-phenyl-ketone (product name: Omnirad 184), 2,2-dimethoxy-1,2-diphenylethane-1-one (product name: Omnirad 651), 2,4,6-trimethylbenzoyl-diphenylphosphine oxide (product name: Omnirad TPO H), and bis(2,4,6-trimethylbenzoyl) phenylphosphine oxide (product name: Omnirad 819).

The photopolymerization initiator may be used alone or in combination of two or more kinds thereof.

In a case where the photosensitive composition contains a photopolymerization initiator, a content thereof is preferably 0.1% to 15% by mass, more preferably 0.5% to 10% by mass, and still more preferably 1% to 5% by mass with respect to the total solid content of the photosensitive composition.

It is preferable that the photosensitive composition does not substantially contain the photopolymerization initiator.

The “does not substantially contain the photopolymerization initiator” means that a content of the photopolymerization initiator with respect to the total solid content of the photosensitive composition may be less than 0.1% by mass, preferably 0% to 0.05% by mass and more preferably 0% to 0.01% by mass.

### <Surfactant>

The photosensitive composition may contain a surfactant.

Examples of the surfactant include an anionic surfactant, a cationic surfactant, a nonionic surfactant, and an amphoteric surfactant, and a nonionic surfactant is preferable.

Examples of the nonionic surfactant include polyoxyethylene higher alkyl ethers, polyoxyethylene higher alkylphenyl ethers, polyoxyethylene glycol higher fatty acid diesters, silicone-based surfactants, and fluorine-based surfactants.

As the surfactant, for example, surfactants described in paragraphs 0120 to 0125 of WO2018/179640A can also be used.

In addition, as the surfactant, surfactants described in paragraph 0017 of JP4502784B and surfactants described in paragraphs 0060 to 0071 of JP2009-237362A can also be used.

Examples of a commercially available product of the fluorine-based surfactant include: MEGAFACE F-171, F-172, F-173, F-176, F-177, F-141, F-142, F-143, F-144, F-437, F-475, F-477, F-479, F-482, F-551, F-551-A, F-552, F-554, F-555-A, F-556, F-557, F-558, F-559, F-560, F-561, F-565, F-563, F-568, F-575, F-780, EXP, MFS-330, MFS-578, MFS-579, MFS-586, MFS-587, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by AGC Inc.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (all of which are manufactured by NEOS COMPANY LIMITED); and U-120E (manufactured by Uni-chem Co., Ltd.).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily (Feb. 22, 2016) and Nikkei Business Daily (Feb. 23, 2016)), for example, MEGAFACE DS-21.

In addition, as the fluorine-based surfactant, a polymer of a fluorine atom-containing vinyl ether compound having a fluorinated alkyl group or a fluorinated alkylene ether group, and a hydrophilic vinyl ether compound is also preferably used.

In addition, as the fluorine-based surfactant, a block polymer can also be used.

In addition, as the fluorine-based surfactant, a fluorine-containing polymer compound including a constitutional unit derived from a (meth)acrylate compound having a fluorine atom and a constitutional unit derived from a (meth)acrylate compound having 2 or more (preferably 5 or more) alkylencoxy groups (preferably ethyleneoxy groups or propyleneoxy groups) can also be preferably used.

In addition, as the fluorine-based surfactant, a fluorine-containing polymer having an ethylenically unsaturated bond-containing group in the side chain can also be used. Examples thereof include MEGAFACE RS-101, RS-102, RS-718K, and RS-72-K (all manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters; PLURONIC L10, L31, L61, L62, 10R5, 17R2, and 25R2 (all of which are manufactured by BASF SE); TETRONIC 304, 701, 704, 901, 904, and 150R1 (all of which are manufactured by BASF SE); SOLSPERSE 20000 (all of which are manufactured by Lubrizol Corporation); NCW-101, NCW-1001, and NCW-1002 (all of which are manufactured by FUJIFILM Wako Pure Chemical Corporation); PIONIN D-6112, D-6112-W, and D-6315 (all of which are manufactured by Takemoto Oil&Fat Co., Ltd.); and OLFINE E1010 and SURFYNOL 104, 400, and 440 (all of which are manufactured by Nissin Chemical Co., Ltd.).

Examples of the silicone-based surfactant include a linear polymer consisting of a siloxane bond and a modified siloxane polymer with an organic group introduced in the side chain or the terminal.

Specific examples of the surfactant include DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.); X-22-4952, X-22-4272, X-22-6266, KF-351A, K354L, KF-355A, KF-945, KF-640, KF-642, KF-643, X-22-6191, X-22-4515, KF-6004, KP-341, KF-6001, KF-6002, KP-101, KP-103, KP-104, KP-105, KP-106, KP-109, KP-112, KP-120, KP-121, KP-124, KP-125, KP-301, KP-306, KP-310, KP-322, KP-323, KP-327, KP-368, KP-369, KP-611, KP-620, KP-621, KP-626, and KP-652 (all of which are manufactured by Shin-Etsu Silicone Co., Ltd.); F-4440, TSF-4300, TSF-4445, TSF-4460, and TSF-4452 (all of which are manufactured by Momentive Performance Materials Co., Ltd.); and BYK300, BYK306, BYK307, BYK310, BYK320, BYK323, BYK330, BYK313, BYK315N, BYK331, BYK333, BYK345, BYK347, BYK348, BYK349, BYK370, BYK377, and BYK378 (all of which are manufactured by BYK Chemie).

The surfactant may be used alone or in combination of two or more kinds thereof.

A content of the surfactant is preferably 0.0001% to 10% by mass, more preferably 0.001% to 5% by mass, and still more preferably 0.005% to 3% by mass with respect to the total solid content of the photosensitive composition.

### <Solvent>

As the solvent, a commonly used solvent can be used without particular limitation.

As the solvent, an organic solvent is preferable.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, 2-propanol, and a mixed solvent thereof.

In a case where the photosensitive composition contains a solvent, a content of the solvent is preferably 20% to 95% by mass, more preferably 60% to 95% by mass, and still more preferably 60% to 85% by mass with respect to the total mass of the photosensitive composition.

The solvent may be used alone, or in combination of two or more kinds thereof.

As the solvent, Solvent described in paragraphs 0054 and 0055 of US2005/282073A can also be used, and the contents of these publications are incorporated in the present specification.

In addition, as the solvent, an organic solvent (high-boiling-point solvent) having a boiling point of 180° C. to 250° C. can also be used as necessary.

In a case where the photosensitive composition according to the embodiment of the present invention forms a photosensitive layer in a transfer film or the like, which will be described later, it is also preferable that the photosensitive layer does not substantially contain the solvent. The fact “does not substantially contain the solvent” means that the content of the solvent may be less than 1% by mass, preferably 0% to 0.5% by mass and more preferably 0% to 0.001% by mass with respect to the total mass of the photosensitive composition (photosensitive layer).

### <Other Additives>

The photosensitive composition may contain other additives as necessary.

Examples the other additives include a plasticizer, a sensitizer, a heterocyclic compound, and an alkoxysilane compound.

Examples of the plasticizer, the sensitizer, the heterocyclic compound, and the alkoxysilane compound include those described in paragraphs 0097 to 0119 of WO2018/179640A.

In addition, the photosensitive composition may further contain, as other additives, a known additive such as a rust inhibitor, metal oxide particles, an antioxidant, a dispersing agent, an acid proliferation agent, a development promoter, a conductive fiber, a colorant, a thermal radical polymerization initiator, a thermal acid generator, an ultraviolet absorber, a thickener, a crosslinking agent, and an organic or inorganic anti-precipitation agent.

Suitable aspects of these components are described in paragraphs 0165 to 0184 of JP2014-085643A, the contents of which are incorporated in the present specification.

### Compound C

In addition, from the viewpoint that the effect of the present invention is more excellent, the photosensitive composition does not contain a compound C having a maximal absorption wavelength of 580 to 800 nm (hereinafter, also referred to as “compound C”), or in a case where the photosensitive composition contains the compound C, a content of the compound C is preferably less than 10% by mass, more preferably less than 3% by mass, and still more preferably substantially 0% by mass with respect to the content of the compound A.

The “substantially 0% by mass of the compound C” means that the content of the compound C may be less than 0.1% by mass, preferably 0% to 0.05% by mass and more preferably 0% to 0.01% by mass with respect to the content of the compound A.

The above-described maximal absorption wavelength of the compound C is measured by dissolving the compound C in acetonitrile. In a case where the compound C is insoluble in acetonitrile, the acetonitrile may be appropriately changed to a solvent for dissolving the compound C.

Examples of the compound C include blue coloring agents such as indigo, methylene blue, phthalocyanine blue, alkali blue, inmine blue, ultramarin, cerulean blue, cobalt blue, prussian blue, and indanthrene.

The photosensitive composition may contain impurities.

Examples of the impurities include sodium, potassium, magnesium, calcium, iron, manganese, copper, aluminum, titanium, chromium, cobalt, nickel, zinc, tin, halogen, and ions of these. Among these, halide ion, sodium ion, and potassium ion are easily mixed as the impurities, so that the following content is particularly preferable.

A content of the impurities in the photosensitive composition is preferably 80 ppm by mass or less, more preferably 10 ppm by mass or less, and still more preferably 2 ppm by mass or less with respect to the total solid content of the photosensitive composition. The content of the impurities in the photosensitive composition may be 1 ppb by mass or more or 0.1 ppm by mass or more with respect to the total solid content of the photosensitive composition.

Examples of a method of setting the impurities in the above-described range include selecting a raw material having a low content of impurities as a raw material for the photosensitive component, preventing the impurities from being mixed in a case of forming the photosensitive composition, and washing and removing the impurities. By such a method, the amount of impurities can be kept within the above-described range.

The impurities can be quantified by a known method such as inductively coupled plasma (ICP) emission spectroscopy, atomic absorption spectroscopy, and ion chromatography.

In addition, in the photosensitive composition, it is preferable that contents of compounds such as benzene, formaldehyde, trichlorethylene, 1,3-butadiene, carbon tetrachloride, chloroform, N,N-dimethylformamide, N,N-dimethylacetamide, and hexane are low. Each content of the compounds in the photosensitive composition is preferably 100 ppm by mass or less, more preferably 20 ppm by mass or less, and still more preferably 4 ppm by mass or less with respect to the total solid content of the photosensitive composition.

The lower limit of the above-described content may be 10 ppb by mass or more or 100 ppb by mass or more with respect to the total solid content of the photosensitive composition. The content of the compounds can be suppressed in the same manner as in the above-described metal as impurities. In addition, the above-described content can be quantified by a known measurement method.

From the viewpoint of improving resolution, a content of water in the photosensitive composition is preferably 0.01% to 1.0% by mass and more preferably 0.05% to 0.5% by mass with respect to the total solid content of the photosensitive composition.

### [Physical Properties of Photosensitive Composition]

It is preferable that the photosensitive composition satisfies the following requirement A and requirement B.

Requirement A: in a case where the following pattern forming method A is performed on a photosensitive layer formed from the photosensitive composition to form a pattern, a film reduction amount represented by Expression (F1) is 50% or less.

film reduction amount(%)={(thickness of photosensitive layer before exposure−thickness of protruding portion of formed pattern)/thickness of photosensitive layer before exposure}×100 Expression (F1):

### <<Pattern Forming Method A>>

The photosensitive composition is applied onto a base material such that a thickness after drying is 3.0 μm to form a coating film, the obtained coating film is dried at 100° C. for 2 minutes to form a photosensitive layer. Next, the photosensitive layer is exposed using an ultra-high pressure mercury lamp under conditions such that an integrated exposure amount measured with a 365 nm wavelength illuminance meter is 500 mJ/cm², through a mask having a line-and-space pattern with a line size of 1 um and a line/space of 1/1. The exposed photosensitive layer is developed by being immersed in a 1% by mass sodium carbonate aqueous solution at a liquid temperature of 23° C. for 35 seconds, rinsed with pure water for 20 seconds, and then blown with air to remove water.

The base material is not particularly limited, but glass (for example, EAGLE XG manufactured by Corning Incorporated) is preferable.

Among the above, the above-described film reduction amount represented by Expression (F1) is more preferably 30% or less and still more preferably 10% or less.

Requirement B: in a case where the following film forming method B is performed on the photosensitive layer formed from the photosensitive composition to form a film, a relative permittivity of the film at 28 GHz, which is measured in an environment of 25° C. and 50% RH, is 3.5 or less.

### <<Film Forming Method B>>

The photosensitive composition is applied onto a base material such that a thickness after drying is 5.0 μm to form a coating film, the obtained coating film is dried at 100° C. for 2 minutes to form a photosensitive layer. Next, the photosensitive layer is exposed using an ultra-high pressure mercury lamp under conditions such that an integrated exposure amount measured with a 365 nm wavelength illuminance meter is 500 mJ/cm².

The relative permittivity can be measured using, for example, a 28 GHz split cylinder type resonator manufactured by KANTO Electronic Application and Development Inc.

The base material is not particularly limited, but a cycloolefin film is preferable.

In addition, in the measurement of the relative permittivity, regarding each of the value of relative permittivity of the exposed base material with the photosensitive layer and the value of relative permittivity of the base material, it is preferable that, at any 15 positions in a plane, an average value obtained by the measurement is determined, and a value (average value) of the relative permittivity of the base material is subtracted from a value (average value) of the relative permittivity of the exposed base material with the photosensitive layer.

In addition, in a case where the photosensitive composition contains an organic solvent in which cycloolefin can be dissolved (for example, methyl ethyl ketone), it is preferable that a test solution in which the organic solvent in the photosensitive composition is replaced with another organic solvent is prepared, and this test solution is used for measuring the above-described relative permittivity.

Among these, the relative permittivity of the above-described film at 28 GHz, measured in an environment of 25° C. and 50% RH, is more preferably 3.2 or less and still more preferably 2.9 or less.

### [Transfer Film]

The transfer film according to the embodiment of the present invention includes a temporary support and a photosensitive layer formed of the photosensitive composition according to the embodiment of the present invention (hereinafter, also simply referred to as “photosensitive layer”).

Hereinafter, the transfer film according to the embodiment of the present invention will be described in detail.

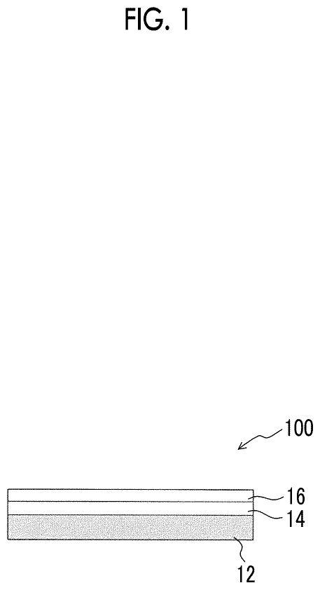

FIG. 1 is a schematic cross-sectional view showing an example of an embodiment of the transfer film according to the present invention.

A transfer film 100 shown in FIG. 1 has a configuration in which a temporary support 12, a photosensitive layer (photosensitive layer formed of the photosensitive composition according to the embodiment of the present invention) 14, and a cover film 16 are laminated in this order.

The cover film 16 may be omitted.

### <<Temporary Support>>

The temporary support is a support which supports the photosensitive layer and can be peeled off from the photosensitive layer.

From the viewpoint that the photosensitive layer can be exposed through the temporary support in a case where the photosensitive layer is exposed in a patterned manner, the temporary support preferably has light-transmitting property.

Here, the “having light-transmitting property” means that a transmittance of light having a main wavelength used for exposure (may be pattern exposure or entire exposure) is 50% or more. From the viewpoint of more excellent exposure sensitivity, the transmittance of the light having the main wavelength used for the exposure is preferably 60% or more, and more preferably 70% or more. Examples of a method of measuring the transmittance include a measuring method using MCPD Series manufactured by OTSUKA ELECTRONICS Co., Ltd.

Specific examples of the temporary support include a glass substrate, a resin film, and paper, and from the viewpoint of more excellent strength and flexibility, a resin film is preferable. Examples of the resin film include a polyethylene terephthalate (PET) film, a cellulose triacetate film, a polystyrene film, and a polycarbonate film. Among these, a biaxially stretched polyethylene terephthalate film is preferable.

From the viewpoint of pattern formability during pattern exposure through the temporary support and transparency of the temporary support, it is preferable that the number of particles, foreign substances, and defects included in the temporary support is small. The number of fine particles, foreign substances, and defects having a diameter of 2 μm or more is preferably 50 pieces/10 mm² or less, more preferably 10 pieces/10 mm² or less, and still more preferably 3 pieces/10 mm² or less. The lower limit thereof is not particularly limited, but can be 1 piece/10 mm² or more.

From the viewpoint of further improving handleability, the temporary support preferably has a layer in which 1 pieces/mm² or more particles with a diameter of 0.5 to 5 μm are present on a surface opposite to the side where the photosensitive layer is formed, and more preferably has a layer in which 1 to 50 pieces/mm² particles with a diameter of 0.5 to 5 μm are present.

A thickness of the temporary support is not particularly limited, but from the viewpoint of ease of handling and excellent general-purpose properties, it is preferably 5 to 200 μm and more preferably 10 to 150 μm.

From the viewpoint of strength as a support, flexibility required for bonding to a substrate for forming a circuit wiring, and light-transmitting property required in a first exposing step, the thickness of the temporary support can be appropriately selected according to a material.

As preferred aspects of the temporary support, for example, descriptions in paragraphs 0017 and 0018 of JP2014-085643A, paragraphs 0019 to 0026 of JP2016-027363A, paragraphs 0041 to 0057 of WO2012/081680A1, and paragraphs 0029 to 0040 of WO2018/179370A1 can be referred to, the contents of which are incorporated in the present specification.

As the temporary support, for example, COSMOSHINE (registered trademark) A4100 manufactured TOYOBO Co., Ltd., LUMIRROR (registered trademark) 16FB40 manufactured by Toray Industries, Inc., or LUMIRROR (registered trademark) 16QS62 (16KS40) manufactured by Toray Industries, Inc. may be used.

In addition, examples of a particularly preferred aspect of the temporary support include a biaxial stretching polyethylene terephthalate film having a thickness of 16 μm, a biaxial stretching polyethylene terephthalate film having a thickness of 12 μm, and a biaxial stretching polyethylene terephthalate film having a thickness of 9 μm.

### <<Photosensitive Layer>>

The photosensitive layer in the transfer film is a layer formed of the photosensitive composition according to the embodiment of the present invention, and for example, the photosensitive layer is preferably a layer substantially composed of only the solid content components of the above-described photosensitive composition. That is, it is preferable that the photosensitive composition constituting the photosensitive layer contains the solid content components (components other than the solvent) which can be contained in the above-described photosensitive composition with the above-described contents.

However, in a case where a photosensitive composition containing a solvent is applied and dried to form a photosensitive layer, the photosensitive layer may contain the solvent because the solvent remains in the photosensitive layer even after drying.

### <Average Thickness of Photosensitive Layer>

An average thickness of the photosensitive layer is preferably 0.5 to 20 μm. In a case where the average thickness of the photosensitive layer is 20 μm or less, resolution of the pattern is more excellent, and in a case where the average thickness of the photosensitive layer is 0.5 μm or more, it is preferable from the viewpoint of pattern linearity. The average thickness of the photosensitive layer is more preferably 0.8 to 15 μm and still more preferably 1.0 to 10 μm. Specific examples of the average thickness of the photosensitive layer include 1.5 μm, 2.0 μm, 3.0 μm, 5.5 μm, and 8.0 μm.

### <Method for Forming Photosensitive Layer>

The photosensitive layer can be formed by applying and drying the photosensitive composition according to the embodiment of the present invention. In a case of forming the photosensitive layer with the photosensitive composition according to the embodiment of the present invention, it is preferable that the photosensitive composition is preferably filtered using a filter having a pore diameter of 0.2 to 30 μm before being provided for formation.

The photosensitive layer can be formed by applying the photosensitive composition onto a temporary support or a cover film, and drying the photosensitive composition.

The applying method is not particularly limited, and examples thereof include known methods such as a slit coating, a spin coating, a curtain coating, and an inkjet coating.

In addition, in a case where other layers described later are formed on the temporary support or the cover film, the photosensitive layer may be formed on the other layers.

### <<Cover Film>>

The transfer film according to the embodiment of the present invention may further include a cover film on a side of the photosensitive layer opposite to the temporary support.

In a case where the transfer film according to the embodiment of the present invention includes a layer of high refractive index, which will be described later, the cover film is preferably disposed on a side opposite to the temporary support (that is, a side opposite to the photosensitive layer) in a case of being viewed from the layer of high refractive index. In this case, for example, the transfer film is a laminate in which “temporary support/photosensitive layer/layer of high refractive index/cover film” are laminated in this order.

The cover film preferably has 5 pieces/m² or less of the number of fisheyes with a diameter of 80 μm or more in the cover film. The “fisheye” means that, in a case where a material is hot-melted, kneaded, extruded, biaxially stretched, cast and/or the like to produce a film, foreign substances, undissolved substances, oxidatively deteriorated substances, and/or the like of the material are incorporated into the film.

The number of particles having a diameter of 3 μm or more, included in the cover film, is preferably 30 particles/mm² or less, more preferably 10 particles/mm² or less, and still more preferably 5 particles/mm² or less. As a result, it is possible to suppress defects caused by ruggedness due to the particles included in the cover film being transferred to the photosensitive resin layer.

An arithmetic average roughness Ra of a surface of the cover film is preferably 0.01 μm or more, more preferably 0.02 μm or more, and still more preferably 0.03 μm or more. In a case where Ra is within such a range, for example, in a case where the transfer film has a long shape, take-up property in a case of winding the transfer film can be improved.

In addition, from the viewpoint of suppressing defects during transfer, Ra is preferably less than 0.50 μm, more preferably 0.40 μm or less, and still more preferably 0.30 μm or less.

Examples of the cover film include a polyethylene terephthalate film, a polypropylene film, a polystyrene film, and a polycarbonate film.

As the cover film, for example, films described in paragraphs 0083 to 0087 and 0093 of JP2006-259138A may be used.

As the cover film, for example, ALPHAN (registered trademark) FG-201 manufactured by Oji F-Tex Co., Ltd., ALPHAN (registered trademark) E-201F manufactured by Oji F-Tex Co., Ltd., Cerapeel (registered trademark) 25WZ manufactured by TORAY ADVANCED FILM CO., LTD., or LUMIRROR (registered trademark) 16QS62 (16KS40) manufactured by Toray Industries, Inc. may be used.

### <<Other Layers>>

The transfer film may include other layers, in addition to those described above. Examples of the other layers include a layer of high refractive index.

In addition, in a case where a layer of high refractive index is formed on the temporary support or the cover film, the photosensitive layer may be formed on the layer of high refractive index.

### <Layer of High Refractive Index>

The layer of high refractive index is preferably disposed adjacent to the photosensitive layer, and is also preferably disposed on a side opposite to the temporary support in a case of being viewed from the photosensitive layer.

The layer of high refractive index is not particularly limited except that the layer has a refractive index of 1.50 or more at a wavelength of 550 nm.

The above-described refractive index of the layer of high refractive index is preferably 1.55 or more and more preferably 1.60 or more.

The upper limit of the refractive index of the layer of high refractive index is not particularly limited, but is preferably 2.10 or less, more preferably 1.85 or less, still more preferably 1.78 or less, and particularly preferably 1.74 or less.

In addition, it is preferable that the refractive index of the layer of high refractive index is higher than the refractive index of the photosensitive layer.

The layer of high refractive index may have photocuring properties (that is, photosensitivity), may have thermosetting properties, or may have both photocuring properties and thermosetting properties.

The aspect in which the layer of high refractive index has photosensitivity, has an advantage, from a viewpoint of collectively patterning the photosensitive layer and the layer of high refractive index transferred onto the base material by photolithography at one time, after the transferring.

The layer of high refractive index preferably has alkali solubility (for example, solubility with respect to weak alkali aqueous solution).

In addition, the layer of high refractive index is preferably a transparent layer.

A film thickness of the layer of high refractive index is preferably 500 nm or less, more preferably 110 nm or less, and still more preferably 100 nm or less.

In addition, the film thickness of the layer of high refractive index is preferably 20 nm or more, more preferably 55 nm or more, still more preferably 60 nm or more, and particularly preferably 70 nm or more.

After the transferring, the layer of high refractive index may be sandwiched between a transparent electrode pattern (preferably, an ITO pattern) and the photosensitive layer to form a laminate together with the transparent electrode pattern and the photosensitive layer. In this case, by reducing a difference in refractive index between the transparent electrode pattern and the layer of high refractive index and a difference in refractive index between the layer of high refractive index and the photosensitive layer, a light reflection is further reduced. As a result, covering property of the transparent electrode pattern is further improved.

For example, in a case where the transparent electrode pattern, the layer of high refractive index, and the photosensitive layer are laminated in this order, this transparent electrode pattern is less likely to be visually recognized in a case of being viewed from the transparent electrode pattern side.

The refractive index of the layer of high refractive index is preferably adjusted in accordance with the refractive index of the transparent electrode pattern.

For example, in a case where the transparent electrode pattern is formed of an oxide of In and Sn (ITO), the refractive index of the transparent electrode pattern is in a range of 1.8 to 2.0, and the refractive index of the layer of high refractive index is preferably 1.60 or more. The upper limit of the refractive index of the layer of high refractive index in this case is not particularly limited, but is preferably 2.1 or less, more preferably 1.85 or less, still more preferably 1.78 or less, and particularly preferably 1.74 or less.

For example, in a case where the transparent electrode pattern is formed of an oxide of In and Zn (Indium Zinc Oxide; IZO), the refractive index of the transparent electrode pattern is more than 2.0, and the refractive index of the layer of high refractive index is preferably 1.70 or more and 1.85 or less.

A method for controlling the refractive index of the layer of high refractive index is not particularly limited, and examples thereof include a method using a resin having a predetermined refractive index alone, a method using a resin and metal oxide particles or metal particles, and a method using a composite body of a metal salt and a resin.

The type of the metal oxide particles or the metal particles is not particularly limited, and known metal oxide particles or metal particles can be used. The metal of the metal oxide particles or the metal particles also includes semimetal such as B, Si, Ge, As, Sb, or Te.

From the viewpoint of transparency, for example, an average primary particle diameter of the particles (the metal oxide particles or the metal particles) is preferably 1 to 200 nm and more preferably 3 to 80 nm.

The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

Specifically, as the metal oxide particles, at least one selected from the group consisting of zirconium oxide particles (ZrO₂ particles), Nb₂O₅ particles, titanium oxide particles (TiO₂ particles), silicon dioxide particles (SiO₂ particles), and composite particles thereof is preferable.

Among these, as the metal oxide particles, for example, from the viewpoint that the refractive index of the layer of high refractive index can be easily adjusted to 1.6 or more, at least one selected from the group consisting of zirconium oxide particles and titanium oxide particles is more preferable.

In a case where the layer of high refractive index contains metal oxide particles, the layer of high refractive index may contain only one kind of metal oxide particles, or may include two or more kinds thereof.

From the viewpoint that covering property of a concealed object such as the electrode pattern is improved and visibility of the concealed object can be effectively improved, a content of the particles (metal oxide particles or metal particles) is preferably 1% to 95% by mass, more preferably 20% to 90% by mass, and still more preferably 40% to 85% by mass with respect to the total mass of the layer of high refractive index.

In a case where titanium oxide is used as the metal oxide particles, the content of the titanium oxide particles is preferably 1% to 95% by mass, more preferably 20% to 90% by mass, and still more preferably 40% to 85% by mass with respect to the total mass of the layer of high refractive index.

Examples of a commercially available product of the metal oxide particles include calcined zirconium oxide particles (manufactured by CIK-Nano Tek., product name: ZRPGM15WT %-F04), calcined zirconium oxide particles (manufactured by CIK-Nano Tek., product name: ZRPGM15WT %-F74), calcined zirconium oxide particles (manufactured by CIK-Nano Tek., product name: ZRPGM15WT %-F75), calcined zirconium oxide particles (manufactured by CIK-Nano Tek., product name: ZRPGM15WT %-F76), zirconium oxide particles (NanoUse OZ-S30M, manufactured by Nissan Chemical Corporation), and zirconium oxide particles (NanoUse OZ-S30K, manufactured by Nissan Chemical Corporation).

The layer of high refractive index preferably contains one or more selected from the group consisting of inorganic particles (the metal oxide particles or the metal particles) having a refractive index 1.50 or more (more preferably 1.55 or more and still more preferably 1.60 or more), a resin having a refractive index 1.50 or more (more preferably 1.55 or more and still more preferably 1.60 or more), and a polymerizable compound having a refractive index 1.50 or more (more preferably 1.55 or more and still more preferably 1.60 or more).

According to this aspect, the refractive index of the layer of high refractive index is easily adjusted to 1.50 or more (more preferably 1.55 or more and particularly preferably 1.60 or more).

In addition, the layer of high refractive index preferably contains a binder polymer, a polymerizable monomer, and particles.

With regard to the components of the layer of high refractive index, components of a curable transparent resin layer, described in paragraphs 0019 to 0040 and 0144 to 0150 of JP2014-108541A, and components of a transparent layer, described in paragraphs 0024 to 0035 and 0110 to 0112 of JP2014-010814A, and components of a composition containing an ammonium salt, described in paragraphs 0034 to 0056 of WO2016/009980A, can be referred to.

In addition, it is also preferable that the layer of high refractive index contains a metal oxidation inhibitor.

In a case where the layer of high refractive index contains a metal oxidation inhibitor, during transferring the layer of high refractive index onto the base material (that is, an object to be transferred), a member that is in direct contact with the layer of high refractive index (for example, a conductive member formed on the base material) can be surface-treated. This surface treatment imparts a metal oxide inhibiting function (protection properties) with respect to the member that is in direct contact with the layer of high refractive index.

The metal oxidation inhibitor is preferably a compound having an aromatic ring including a nitrogen atom. The compound having an aromatic ring including a nitrogen atom may have a substituent.

The aromatic ring including a nitrogen atom is preferably an imidazole ring, a triazole ring, a tetrazole ring, a thiazole ring, a thiadiazole ring, or a fused ring of any one of these rings and another aromatic ring, and more preferably an imidazole ring, a triazole ring, a tetrazole ring, or a fused ring of any one of these rings and another aromatic ring.

The “another aromatic ring” forming the fused ring may be a homocyclic ring or a heterocyclic ring; and is preferably a homocyclic ring, more preferably a benzene ring or a naphthalene ring, and still more preferably a benzene ring.

As the metal oxidation inhibitor, imidazole, benzimidazole, tetrazole, 5-amino-1H-tetrazole, mercaptothiadiazole, or benzotriazole is preferable, and imidazole, benzimidazole, 5-amino-1H-tetrazole, or benzotriazole is more preferable.

A commercially available product may be used as the metal oxidation inhibitor, and as the commercially available product, for example, BT120 manufactured by JOHOKU CHEMICAL CO., LTD., including benzotriazole, can be preferably used.

In a case where the layer of high refractive index contains a metal oxidation inhibitor, a content of the metal oxidation inhibitor is preferably 0.1% to 20% by mass, more preferably 0.5% to 10% by mass, and still more preferably 1% to 5% by mass with respect to the total solid content of the layer of high refractive index.

The layer of high refractive index may contain a component other than the above-described components.

Examples of other components which can be contained in the layer of high refractive index include components same as those which can be contained in the photosensitive layer.

The layer of high refractive index also preferably contains a surfactant.

A method for forming the layer of high refractive index is not particularly limited.

Examples of the method of forming the layer of high refractive index include a forming method in which a composition for forming the layer of high refractive index in an aspect of including an aqueous solvent is applied onto the above-described photosensitive layer which has been formed on the temporary support, and the composition is dried as necessary.

The composition for forming the layer of high refractive index can contain each component of the above-described layer of high refractive index.

For example, the composition for forming the layer of high refractive index includes a binder polymer, a polymerizable monomer, particles, and an aqueous solvent.

In addition, as the composition for forming the layer of high refractive index, a composition having an ammonium salt, described in paragraphs 0034 to 0056 of WO2016/009980A, is also preferable.

The photosensitive layer and the layer of high refractive index are preferably achromatic. Specifically, in CIE1976 (L*, a*, b*) color space of the total reflection (incidence angle: 8°, light source: D-65 (visual field: 2°)), the L′ value is preferably 10 to 90, the a* value is preferably −1.0 to 1.0, and the b* value is preferably −1.0 to 1.0.

### <Other Layers>

The transfer film may include a layer other than the above-described layers (hereinafter, also referred to as “other layers”). Examples of the other layers include an interlayer and a thermoplastic resin layer, and known layers can be appropriately adopted.

A preferred aspect of the thermoplastic resin layer is described in paragraphs 0189 to 0193 of JP2014-085643A, and preferred aspects of layers other than the above each are described in paragraphs 0194 to 0196 of JP2014-085643A, and the contents of these publications are incorporated in the present specification.

### [Pattern Forming Method]

The pattern forming method related to the present invention (also referred to as “pattern forming method according to the embodiment of the present invention”) is not particularly limited as long as it is a pattern forming method using the photosensitive composition according to the embodiment of the present invention or the transfer film according to the embodiment of the present invention, and it is preferable to include a step of forming a photosensitive layer on a base material, a step of exposing the photosensitive layer in a patterned manner, and a step of developing (in particular, alkali-developing) the exposed photosensitive layer. In a case where the above-described development is an organic solvent development, it is preferable to include a step of further exposing the obtained pattern.

Examples of specific embodiments of the pattern forming method according to the embodiment of the present invention include pattern forming methods of an embodiment 1 and an embodiment 2.

Hereinafter, each step of the pattern forming methods of the embodiment 1 and the embodiment 2 will be described in detail.

### [Pattern Forming Method of Embodiment 1]

A pattern forming method of an embodiment 1 includes steps X1 to X3. The following step X2 corresponds to a step of reducing the content of the carboxy group derived from the compound A in the photosensitive layer by the exposure. However, in a case where the developer in the above-described step X3 is an organic solvent-based developer, it is preferable that a step X4 is further provided after the step X3.
Step X1: step of forming a photosensitive layer on a base material
Step X2: step of exposing the photosensitive layer in a patterned manner
Step X3: step of developing the photosensitive layer with a developer (for example, an alkali developer or an organic solvent-based developer)
Step X4: step of further exposing the pattern formed by the development after the developing step of the step X3

In a case where an alkali developer is used as the developer in the step X3, it is preferable that the above-described photosensitive layer is a photosensitive layer formed from the photosensitive composition of the embodiment X-1-a1 and the photosensitive composition of the embodiment X-1-a2. In a case where an organic solvent-based developer is used as the developer in the step X3, it is preferable that the above-described photosensitive layer is a photosensitive layer formed from the photosensitive composition of the embodiment X-1-a1.

The pattern forming method of the embodiment 1 is preferably adopted to the photosensitive layer formed from the photosensitive composition of the embodiment X-1-a1 and the photosensitive composition of the embodiment X-1-a2 described above.

In addition, it is preferable that the pattern forming method of the embodiment 1 includes a step of peeling off the temporary support between the step X1 and the step X2 or between the step X2 and the step X3.

### <<<Step X1>>>

The pattern forming method of the embodiment 1 includes a step of forming a photosensitive layer on a base material.

### <<Base Material>>

The base material is not particularly limited, and examples thereof include a glass substrate, a silicon substrate, a resin substrate, and a substrate having a conductive layer. Examples of the substrate included in the substrate having a conductive layer include a glass substrate, a silicon substrate, and a resin substrate.

The above-described base material is preferably transparent.

A refractive index of the above-described base material is preferably 1.50 to 1.52.

The above-described base material may be composed of a translucent substrate such as a glass substrate, and for example, tempered glass typified by Gorilla glass of Corning Incorporated can also be used. In addition, as the material contained in the above-described base material, materials used in JP2010-086684A, JP2010-152809A, and JP2010-257492A are also preferable.

In a case where the above-described base material includes a resin substrate, as the resin substrate, it is more preferable to use a resin film having a small optical distortion and/or a high transparency. Specific examples of the material include polyethylene terephthalate (PET), polyethylene naphthalate, polycarbonate, triacetyl cellulose, and a cycloolefin polymer.

As the substrate included in the substrate having a conductive layer, from the viewpoint of manufacturing by roll-to-roll method, a resin substrate is preferable and a resin film is more preferable.

Examples of the conductive layer include any conductive layer used for general circuit wiring or touch panel wiring.

As the conductive layer, from the viewpoint of conductivity and fine line formability, one or more layers selected from the group consisting of a metal layer (a metal foil or the like), a conductive metal oxide layer, a graphene layer, a carbon nanotube layer, and a conductive polymer layer are preferable, a metal layer is more preferable, and a copper layer or a silver layer is still more preferable.

In addition, the conductive layer in the substrate having a conductive layer may be one layer or two or more layers.

In a case where the substrate having a conductive layer includes two or more conductive layers, it is preferable that each conductive layer is a conductive layer formed of different materials.

Examples of a material of the conductive layer include simple substances of metal and conductive metal oxides.

Examples of the simple substance of metal include Al, Zn, Cu, Fe, Ni, Cr, Mo, Ag, and Au.

Examples of the conductive metal oxide include indium tin oxide (ITO), indium zinc oxide (IZO), and SiO₂. The “conductive” refers to that a volume resistivity is less than 1×10⁶ Ω·cm, and the volume resistivity is preferably less than 1×10⁴ Ω·cm.

In a case where the number of conductive layers in the substrate having a conductive layer is 2 or more, it is preferable that at least one conductive layer among the conductive layers includes the conductive metal oxide.

The conductive layer is preferably an electrode pattern corresponding to a sensor in a visual recognition portion used for a capacitive touch panel or a wiring line for a peripheral wiring portion.

In addition, the conductive layer is preferably a transparent layer.

### <<Procedure of Step X1>>

The step X1 is preferably a step of forming a photosensitive layer on a base material using the above-described photosensitive composition or the above-described transfer film.

Examples of a method of forming the photosensitive layer using the photosensitive composition include a method of applying the photosensitive composition onto the base material and, as necessary, drying the coating film to form the photosensitive layer on the base material. Examples of such a method of forming the photosensitive layer on the base material include the same method as the method of forming the photosensitive layer described in the transfer film above.

In addition, as the method of forming the photosensitive layer using the transfer film, the step X1 is preferably a step of bringing a surface of the photosensitive layer in the transfer film on an opposite side of the temporary support side into contact with the base material to bond the transfer film and the base material. Such a step is also particularly referred to as a step X1b.

The above-described step X1b is preferably a bonding step of pressurization by a roll or the like and heating. A known laminator such as a laminator, a vacuum laminator, and an auto-cut laminator can be used for the bonding.

The step X1b is preferably performed by a roll-to-roll method, and therefore, the base material to which the transfer film is bonded is preferably a resin film or a resin film having a conductive layer.

Hereinafter, the roll-to-roll method will be described.

The roll-to-roll method refers to a method in which, as the base material, a base material which can be wound up and unwound is used, a step (also referred to as an “unwinding step”) of unwinding the base material before any of the steps included in the pattern forming method according to the embodiment of the present invention, a step (also referred to as a “winding step”) of winding the base material is included after any of the steps, and at least one of the steps (preferably, all steps or all steps other than the heating step) is performed while transporting the base material.

An unwinding method in the unwinding step and a winding method in the winding step are not particularly limited, and a known method may be used in the manufacturing method to which the roll-to-roll method is adopted.

### <<Step X2>>

The pattern forming method according to the embodiment 1 includes a step (step X2) of exposing the photosensitive layer in a patterned manner after the above-described step X1. The step X2 corresponds to a step of reducing the content of the carboxy group derived from the compound A in the photosensitive layer by the exposure. More specifically, it is preferable that, by using light having a wavelength which excites the specific structure of the compound B in the photosensitive layer, the photosensitive layer is exposed in a patterned manner.

Detailed arrangement and specific size of the pattern in the exposing step are not particularly limited.

For example, in a case where the pattern forming method of the embodiment 1 is adopted to the manufacturing of a circuit wiring, from the viewpoint of improving display quality of a display device (for example, a touch panel) including an input device having the circuit wiring manufactured by the pattern forming method of the embodiment 1, and viewpoint of reducing an area occupied by a lead-out wiring as much as possible, at least a part of the pattern (in particular, a portion corresponding to a portion of the electrode pattern of the touch panel and the lead-out wiring) is preferably a thin line having a width of 100 μm or less, and more preferably a thin line having a width of 70 μm or less.

As a light source used for the exposure, any light source which emits light in a wavelength range capable of reducing the content of the carboxy group derived from the compound A in the photosensitive layer (light having a wavelength which excites the specific structure of the compound B in the photosensitive layer; for example, light in a wavelength range of 254 nm, 313 nm, 365 nm, 405 nm, and the like (preferably, light having a wavelength of 365 nm)) can be appropriately selected. Specific examples thereof include an ultra-high pressure mercury lamp, a high pressure mercury lamp, a metal halide lamp, and a light emitting diode (LED).

An exposure amount is preferably 10 to 10,000 mJ/cm² and more preferably 50 to 3,000 mJ/cm².

In a case where the step X1 is the step X1b, in the step X2, the temporary support may be peeled off from the photosensitive layer and then the pattern exposure may be performed, or before peeling off the temporary support, the pattern exposure may be performed through the temporary support and then the temporary support may be peeled off. In order to prevent mask contamination due to contact between the photosensitive layer and the mask and to avoid an influence of foreign substance adhering to the mask on the exposure, it is preferable to perform the pattern exposure without peeling off the temporary support. The pattern exposure may be an exposure through the mask or a direct exposure using a laser or the like.

In a case where the step X1 is the step X1b, before the step X3 described later, the temporary support is peeled off from the photosensitive layer.

### <<Step X3>>

The pattern forming method of the embodiment 1 includes a step (step X3) of, after the above-described step X2, developing the photosensitive layer exposed in a patterned manner with a developer (alkali developer or organic solvent-based developer).

By reducing the content of the carboxy group in the photosensitive layer of the exposed portion, a difference in solubility (dissolution contrast) in the developer may occur between the exposed portion and the non-exposed portion of the photosensitive layer which has undergone the step X2. By forming the dissolution contrast in the photosensitive layer, it is possible to form a pattern in the step X3. In a case where the developer in the above-described step X3 is an alkali developer, the non-exposed portion is removed and a negative pattern is formed by performing the above-described step X3. On the other hand, in a case where the developer in the above-described step X3 is an organic solvent-based developer, the exposed portion is removed and a positive pattern is formed by performing the above-described step X3. For the obtained positive pattern, it is necessary to perform a treatment for reducing the content of the carboxy group derived from the compound A by the step X4 described later.

### (Alkali Developer)

The alkali developer is not particularly limited as long as the non-exposed portion of the photosensitive resin layer can be removed, and a known developer such as a developer described in JP1993-072724A (JP-H5-072724A) can be used.

As the alkali developer, for example, an alkali aqueous solution-based developer including a compound having a pKa of 7 to 13 at a concentration of 0.05 to 5 mol/liter (L) is preferable.

In addition, the alkali developer may further contain a water-soluble organic solvent, a surfactant, and the like. As the alkali developer, for example, developers described in paragraph 0194 of WO2015/093271A are preferable.

A concentration of water in the alkali developer is preferably 50% by mass or more, more preferably 60% by mass or more, still more preferably 85% by mass or more, particularly preferably 90% by mass or more, and most preferably 95% by mass or more. The upper limit value thereof is, for example, less than 100% by mass.

### (Organic Solvent-Based Developer)

The organic solvent-based developer is not particularly limited as long as it can remove the exposed portion of the photosensitive resin layer, and for example, a developer including an organic solvent such as a ketone-based solvent, an ester-based solvent, an alcohol-based solvent, an amide-based solvent, an ether-based solvent, and a hydrocarbon-based solvent can be used.

In the organic solvent-based developer, a plurality of organic solvents may be mixed, or may be mixed with an organic solvent other than the above or water and used. However, in order to fully exert the effect of the present invention, a moisture content of the organic solvent-based developer as a whole is preferably less than 10% by mass, and the organic solvent-based developer is more preferably substantially free of water. A concentration of the organic solvent (in a case of mixing a plurality of organic solvents, a total thereof) in the organic solvent-based developer is preferably 50% by mass or more, more preferably 60% by mass or more, still more preferably 85% by mass or more, particularly preferably 90% by mass or more, and most preferably 95% by mass or more. The upper limit value thereof is, for example, 100% by mass or less.

A development method is not particularly limited, and may be any of a puddle development, a shower development, a spin development, a dip development, or the like. Here, as the shower development, unnecessary portions can be removed by spraying the developer on the photosensitive resin layer after the exposure with a shower. In addition, after the development, it is also preferable to spray a washing agent and the like with a shower and rub with a brush and the like to remove the developing residue. A liquid temperature of the developer is preferably 20° C. to 40° C.

The pattern forming method of the embodiment 1 may or may not further include a post-baking step of heat-treating a pattern including the photosensitive layer obtained by development.

The post-baking is preferably performed in an environment of 8.1 to 121.6 kPa, and more preferably performed in an environment of 50.66 kPa or more. On the other hand, it is more preferably performed in an environment of 111.46 kPa or less, and still more preferably performed in an environment of 101.3 kPa or less.

The temperature of the post-baking is preferably 80° C. to 250° C., more preferably 110° C. to 170° C., and still more preferably 130° C. to 150° C.

The time of the post-baking is preferably 1 to 60 minutes, more preferably 2 to 50 minutes, and still more preferably 5 to 40 minutes.

The post-baking may be performed in an air environment or a nitrogen replacement environment.

### <<Step X4>>

In a case where the developer in the above-described step X3 is an organic solvent-based developer, the step X4 is performed on the obtained positive pattern. The step X4 corresponds to a step of exposing the positive pattern obtained in the step X3 to reduce the content of the carboxy group derived from the compound A. More specifically, it is preferable that, by using light having a wavelength which excites the specific structure of the compound B in the photosensitive layer, the photosensitive layer is exposed in a patterned manner.

A light source and exposure amount used for the exposure are the same as the light source and exposure amount described in the step X1, and suitable aspects thereof are also the same.

### [Pattern Forming Method of Embodiment 2]

The pattern forming method of an embodiment 2 includes a step Y1, a step Y2P, and a step Y3 in this order, and further includes a step Y2Q (step of further exposing the photosensitive layer exposed in the step Y2P) between the step Y2P and the step Y3 or after the step Y3.
Step Y1: step of forming a photosensitive layer on a base material
Step Y2P: step of exposing the photosensitive layer
Step Y3: step of developing the photosensitive layer with a developer

The pattern forming method of the embodiment 2 corresponds to an applicable aspect in which the photosensitive layer further includes a photopolymerization initiator and a polymerizable compound. Therefore, the pattern forming method of the embodiment 2 is preferably adopted to the photosensitive layer formed from the photosensitive composition of the embodiment X-1-a3 described above.

Hereinafter, the pattern forming method of the embodiment 2 will be described, but the step Y1 and the step Y3 are the same as the step X1 and the step X3, respectively, so that the description thereof will be omitted.

It is sufficient that the step Y3 is performed at least after the step Y2P, and the step Y3 may be performed between the step Y2P and the step Y2Q.

The pattern forming method of the embodiment 2 may or may not further include, after the step Y3, a post-baking step of heat-treating a pattern including the photosensitive layer obtained by development. The post-baking step can be performed by the same method as the post-baking step which may be included in the above-described pattern forming method of the embodiment 1. In a case where the step Y3 is performed between the step Y2P and the step Y2Q, the post-baking step may be performed before the step Y2Q or after the step Y2Q as long as it is performed after the step Y3.

In addition, it is preferable that the pattern forming method of the embodiment 2 includes a step of peeling off the temporary support between the step Y1 and the step Y2P or between the step Y2P and the step Y3.

<<Step Y2P and step Y2Q>>

The pattern forming method of the embodiment 2 includes a step (step Y2P) of exposing the photosensitive layer through the step Y1 and a step (step Y2Q) of further exposing the exposed photosensitive layer.

One of the exposure treatments (the step Y2P and the step Y2Q) is an exposure for mainly reducing the content of the carboxy group derived from the compound A by the exposure, and the other of the exposure treatments (the step Y2P and the step Y2Q) is an exposure for mainly causing a polymerization reaction of the polymerizable compound based on the photopolymerization initiator. In addition, the exposure treatments (the step Y2P and the step Y2Q) may be either the entire exposure or the pattern exposure, but any one of the exposure treatments is the pattern exposure.

For example, in a case where the step Y2P is a pattern exposure for reducing the content of the carboxy group derived from the compound A by the exposure, the developer used in the step Y3 may be an alkali developer or an organic solvent-based developer. However, in a case of developing with an organic solvent-based developer, the step Y2Q is usually performed after the step Y3, and in the developed photosensitive layer (pattern), the polymerization reaction of the polymerizable compound based on the photopolymerization initiator occurs, and the content of the carboxy group derived from the compound A is reduced.

In addition, for example, in a case where the step Y2P is a pattern exposure for causing a polymerization reaction of the polymerizable compound based on the photopolymerization initiator, the developer used in the step Y3 is usually an alkali developer. In this case, the step Y2Q may be performed before or after the step Y3, and the step Y2Q in a case of being performed before the step Y3 is usually a pattern exposure.

In the step Y2P and the step Y2Q, as a light source used for the exposure, any light source which emits light in a wavelength range capable of reducing the content of the carboxy group derived from the compound A in the photosensitive layer (light having a wavelength which excites the specific structure of the compound B in the photosensitive layer; examples thereof include light in a wavelength range of 254 nm, 313 nm, 365 nm, 405 nm, or the like (preferably, light having a wavelength of 365 nm)) or light in a wavelength range capable of causing a reaction of the polymerizable compound based on the photopolymerization initiator in the photosensitive layer (light having a wavelength which exposes the photopolymerization initiator; for example, 254 nm, 313 nm, 365 nm, 405 nm, or the like) can be appropriately selected. Specific examples thereof include an ultra-high pressure mercury lamp, a high pressure mercury lamp, a metal halide lamp, and a light emitting diode (LED).

In the exposure for reducing the content of the carboxy group derived from the compound A in the photosensitive layer, an exposure amount is preferably 10 to 10,000 mJ/cm² and more preferably 50 to 3,000 mJ/cm².

In the exposure for causing a reaction of the polymerizable compound based on the photopolymerization initiator in the photosensitive layer, an exposure amount is preferably 5 to 200 mJ/cm² and more preferably 10 to 150 mJ/cm².

In a case where the transfer film is used in the step Y1, in the step Y2P and the step Y2Q, the temporary support may be peeled off from the photosensitive layer and then the pattern exposure may be performed, or before peeling off the temporary support, the pattern exposure may be performed through the temporary support and then the temporary support may be peeled off. In order to prevent mask contamination due to contact between the photosensitive layer and the mask and to avoid an influence of foreign substance adhering to the mask on the exposure, it is preferable to perform the pattern exposure without peeling off the temporary support. The pattern exposure may be an exposure through the mask or a direct exposure using a laser or the like.

Detailed arrangement and specific size of the pattern in the exposing step are not particularly limited.

For example, in a case where the pattern forming method of the embodiment 2 is adopted to the manufacturing of a circuit wiring, from the viewpoint of improving display quality of a display device (for example, a touch panel) including an input device having the circuit wiring manufactured by the pattern forming method of the embodiment 2, and viewpoint of reducing an area occupied by a lead-out wiring as much as possible, at least a part of the pattern (in particular, a portion corresponding to a portion of the electrode pattern of the touch panel and the lead-out wiring) is preferably a thin line having a width of 100 μm or less, and more preferably a thin line having a width of 70 μm or less.

### [Suitable Aspect]

As the pattern forming method, it is also preferable to include a step Y1, a step Y2A, and a step Y3 in this order. In addition, it is also preferable that the pattern forming method further includes a step Y2B after the step Y3. It is also preferable that one of the step Y2A or the step Y2B is an exposing step for reducing the content of the carboxy group described from the compound A by exposure, and the other one is an exposing step for mainly causing a polymerization reaction of the polymerizable compound based on the photopolymerization initiator.
Step Y1: step of forming a photosensitive layer on a base material
Step Y2A: step of exposing the photosensitive layer in a patterned manner
Step Y3: step of developing the photosensitive layer with an alkali developer to form a patterned photosensitive layer
Step Y2B: step of exposing the patterned photosensitive layer

In addition, it is preferable that the above-described pattern forming method includes a step of peeling off the temporary support between the step Y1 and the step Y2A or between the step Y2A and the step Y3.

The above-described step Y2A is preferably an exposing step for causing a polymerization reaction of the polymerizable compound based on the photopolymerization initiator, and the above-described step Y2B is preferably an exposing step for reducing the content of the carboxy group derived from the compound A by the exposure.

### [Optional Step Which May be Included in Pattern Forming Method]

The pattern forming method (the pattern forming method of the embodiment 1, the pattern forming method of the embodiment 2, the pattern forming method of the above-described suitable aspect, or the like) may include any steps (other steps) in addition to those described above. Examples thereof include the following steps, but the optional step is not limited to the following steps.

### <<Cover Film Peeling Step>>

In the above-described pattern forming method, in a case where the transfer film includes a cover film, it is preferable to include a step (hereinafter, also referred to as a “cover film peeling step”) of peeling off the cover film of the transfer film. A method of peeling off the cover film is not particularly limited, and a known method can be adopted.
<<Step of Reducing Visible Light Reflectivity>>

In a case where the substrate is the substrate having a conductive layer, the above-described pattern forming method may further include a step of performing a treatment of reducing a visible light reflectivity of the conductive layer. In a case where the above-described substrate is a substrate having a plurality of conductive layers, the treatment of reducing the visible light reflectivity may be performed on some conductive layers or all conductive layers.

Examples of the treatment of reducing the visible light reflectivity include an oxidation treatment. For example, by oxidizing copper to copper oxide, the visible light reflectivity of the conductive layer can be reduced due to blackening.

Preferred aspects of the treatment of reducing the visible light reflectivity are described in paragraphs 0017 to 0025 of JP2014-150118A, and paragraphs 0041, 0042, 0048, and 0058 of JP2013-206315A, and the contents of these publications are incorporated in the present specification.

### <<Etching Step>>

In a case where the substrate is the substrate having a conductive layer, the above-described pattern forming method preferably includes a step (etching step) of etching, using the pattern formed by the step X3 (or the step X4) and the step Y3 (or the step Y2B) as an etching resist film, the conductive layer in a region where the etching resist film is not disposed.

As a method of the etching treatment, a method by wet etching, which is described in paragraphs 0048 to 0054 of JP2010-152155A, a method by dry etching such as a known plasma etching, or the like can be adopted.

For example, examples of the method of the etching treatment include a wet etching method by immersing in an etchant, which is generally performed. As the etchant used for the wet etching, an acidic type or alkaline type etchant may be appropriately selected according to the etching target.

Examples of the acidic type etchant include aqueous solutions of acidic component alone, such as hydrochloric acid, sulfuric acid, hydrofluoric acid, and phosphoric acid, and mixed aqueous solutions of an acidic component and a salt such as ferric chloride, ammonium fluoride, and potassium permanganate. As the acidic component, a component in which a plurality of acidic components is combined may be used.

Examples of the alkaline type etchant include aqueous solutions of alkaline component alone, such as sodium hydroxide, potassium hydroxide, ammonia, organic amine, and a salt of organic amine such as tetramethylammonium hydroxide, and mixed aqueous solutions of an alkaline component and a salt such as potassium permanganate. As the alkaline component, a component in which a plurality of alkaline components is combined may be used.

A temperature of the etchant is not particularly limited, but is preferably 45° C. or lower. In the method for manufacturing a circuit wiring according to the embodiment of the present invention, the pattern formed by the step X3 (or the step X4) and the step Y3 used as the etching resist film preferably exhibits particularly excellent resistance to the acidic and alkaline etchant in a temperature range of 45° C. or lower. With the above-described configuration, the etching resist film is prevented from peeling off during the etching step, and a portion where the etching resist film does not exist is selectively etched.

After the etching step, in order to prevent contamination of the process line, a washing step of washing the etched substrate and a drying step of drying the washed substrate may be performed as necessary.

### Other Embodiments

In the above-described pattern forming method, it is also preferable to use a substrate having a plurality of conductive layers on both surfaces, and sequentially or simultaneously form patterns on the conductive layers formed on both surfaces.

With such a configuration, it is possible to form a first conductive pattern on one surface of the substrate and form a second conductive pattern on the other surface. It is also preferable to form the patterns from both surfaces of the base material by the roll-to-roll.

### [Method for Manufacturing Circuit Wiring]

The method for manufacturing a circuit wiring according to the embodiment of the present invention is not particularly limited as long as it is a method for manufacturing a circuit wiring using the above-described photosensitive composition or the above-described transfer film, but it is preferable to include a step of forming a photosensitive layer on a substrate having a conductive layer using the photosensitive composition or the transfer film (photosensitive layer forming step), a step of exposing the photosensitive layer in a patterned manner (first exposing step), a step of developing the exposed photosensitive layer with an alkali developer to form a pattern (developing step), a step of etching the conductive layer in a region where the pattern is not disposed (etching step) or a step of plating the conductive layer in a region where the pattern is not disposed (plating step), a step of peeling off the pattern (peeling step), and a step of, in a case of performing the plating, removing the conductive layer exposed by the step of peeling off the pattern to form a wiring pattern on the substrate (removal step).

In the method for manufacturing a circuit wiring according to the embodiment of the present invention, all of the photosensitive layer forming step, the first exposing step, and the alkali developing step can be performed by the same procedure as in the step X1, the step X2, and the step X3 of the pattern forming method of the embodiment 1 described above.

In addition, in a case where the photosensitive layer is a photosensitive layer formed from the photosensitive composition of the embodiment X-1-a3, a treatment of exposing the pattern (second exposing treatment) may be further performed before and after the development treatment. The second exposure treatment can be performed by the same procedure as in the step Y2Q of the pattern forming method of the embodiment 2 described above.

In addition, the substrate having a conductive layer, which is used in the method for manufacturing a circuit wiring according to the embodiment of the present invention, is the same as the substrate having a conductive layer, which is used in the above-described step X1. In addition, the method for manufacturing a circuit wiring according to the embodiment of the present invention may include a step other than the above-described steps. Examples of other steps include the same steps as the optional step which may be included in the pattern forming methods of the embodiment 1 and the embodiment 2.

In the method for manufacturing a circuit wiring according to the embodiment of the present invention, five steps of the above-described bonding step, the above-described first exposing step, the above-described developing step, the above-described second exposing step, and the above-described etching step are regarded as one set, and it is also preferable to repeat the set a plurality of times.

The film used as the etching resist film can also be used as a protective film (permanent film) for the formed circuit wiring.

Hereinafter, the etching step, the plating step, the peeling step, and the removal step will be described in detail.

### <<Etching Step>>

The etching step is a step of etching or plating the above-described conductive layer in a region where the pattern is not disposed.

As a method of the etching treatment, a method by wet etching, which is described in paragraphs 0048 to 0054 of JP2010-152155A, a method by dry etching such as a known plasma etching, or the like can be adopted.

For example, examples of the method of the etching treatment include a wet etching method by immersing in an etchant, which is generally performed. As the etchant used for the wet etching, an acidic type or alkaline type etchant may be appropriately selected according to the etching target.

Examples of the acidic type etchant include aqueous solutions of acidic component alone, such as hydrochloric acid, sulfuric acid, hydrofluoric acid, and phosphoric acid, and mixed aqueous solutions of an acidic component and a salt such as ferric chloride, ammonium fluoride, and potassium permanganate. As the acidic component, a component in which a plurality of acidic components is combined may be used.

Examples of the alkaline type etchant include aqueous solutions of alkaline component alone, such as sodium hydroxide, potassium hydroxide, ammonia, organic amine, and a salt of organic amine such as tetramethylammonium hydroxide, and mixed aqueous solutions of an alkaline component and a salt such as potassium permanganate. As the alkaline component, a component in which a plurality of alkaline components is combined may be used.

A temperature of the etchant is not particularly limited, but is preferably 45° C. or lower. In the method for manufacturing a circuit wiring according to the embodiment of the present invention, the pattern formed by the step X3 (or the step X4) and the step Y3 used as the etching resist film preferably exhibits particularly excellent resistance to the acidic and alkaline etchant in a temperature range of 45° C. or lower. With the above-described configuration, the etching resist film is prevented from peeling off during the etching step, and a portion where the etching resist film does not exist is selectively etched.

After the etching step, in order to prevent contamination of the process line, a washing step of washing the etched substrate and a drying step of drying the washed substrate may be performed as necessary.

### <<Plating Step>>

The plating step is a step of forming a plating layer by a plating treatment on the conductive layer in a region where the pattern is not disposed (the conductive layer exposed on the surface by the developing step).

Examples of a method of the plating treatment include an electrolytic plating method and an electroless plating method, and from the viewpoint of productivity, an electrolytic plating method is preferable.

In a case where the plating step is performed, a plating layer having the same pattern shape as the region where the pattern is not disposed (an opening portion of the pattern) on the substrate having a conductive layer is obtained.

Examples of a metal contained in the plating layer include known metals.

Specific examples thereof include metals such as copper, chromium, lead, nickel, gold, silver, tin, and zinc, and alloys of these metals.

Among these, the plating layer preferably contains copper or an alloy thereof. In addition, the plating layer preferably contains copper as a main component.

A thickness of the plating layer is preferably 0.1 μm or more and more preferably 1 μm or more. The upper limit thereof is preferably 20 μm or less.

### <<Protective Layer Forming Step>>

It is also preferable that a protective layer forming step is provided between the plating treatment step and the peeling step described later.

The protective layer forming step is a step of forming a protective layer on the plating layer.

As a material of the protective layer, a material having resistance to a stripper and/or an etchant in the peeling step and/or the removal step is preferable. Examples thereof include metals such as nickel, chromium, tin, zinc, magnesium, gold, and silver, alloys thereof, and resins thereof, and nickel or chromium is preferable.

Examples of a method of forming the protective layer include an electroless plating method and an electrolytic plating method, and an electrolytic plating method is preferable.

A thickness of the protective layer is preferably 0.3 μm or more and more preferably 0.5 μm or more. The upper limit thereof is preferably 3.0 μm or less and more preferably 2.0 μm or less.

### <<Peeling Step>>

The peeling step is a step of peeling off the pattern.

Examples of a method of peeling off the pattern include a method of removing the pattern by chemical treatment, and a method of removing the pattern using a stripper is preferable.

Examples of the method of peeling off the pattern include a method of removing the pattern with a known method such as a spraying method, a shower method, and a puddle method, using the stripper.

Examples of the stripper include a stripper in which an alkaline compound is dissolved in at least one selected from the group consisting of water, dimethyl sulfoxide, and N-methylpyrrolidone.

Examples of the alkaline compound (a compound which is dissolved in water to be alkaline) include alkaline inorganic compounds such as sodium hydroxide and potassium hydroxide, alkaline organic compounds such as a primary amine compound, a secondary amine compound, a tertiary amine compound, and a quaternary ammonium salt compound.

Examples of a suitable aspect of the peeling method include a method of immersing the substrate having a pattern as a removal target in a stripper under stirring, having a liquid temperature of 50° C. to 80° C., for 1 to 30 minutes.

### <<Removal Step>>

In a case where the plating step is included, it is preferable to have the removal step.

The removal step is a step of removing the conductive layer exposed by the peeling step to obtain a wiring pattern on the substrate.

In the removal step, the plating layer formed by the plating step is used as an etching resist to carry out an etching treatment of the conductive layer positioned in a non-pattern forming region (in other words, a region not protected by the plating layer).

The method of removing a part of the conductive layer is not particularly limited, but it is preferable to use a known etchant.

Examples of one aspect of known etchant include a ferric chloride solution, a cupric chloride solution, an ammonia alkali solution, a sulfuric acid-hydrogen peroxide mixed solution, and a phosphoric acid-hydrogen peroxide mixed solution.

In a case where the removal step is performed, the conductive layer exposed on the surface of the substrate is removed, a plating layer (wiring pattern) having a pattern shape remains, and a laminate having a wiring pattern is obtained.

A line width of the wiring pattern to be formed is preferably 8 μm or less and more preferably 6 μm or less. The lower limit thereof is often 1 μm or more.

The use of the pattern formed by the above-described pattern forming method is not particularly limited, and can be used as various protective films or insulating films.

Specific examples thereof include the use as a protective film (permanent film) which protects a conductive pattern, the use as an interlayer insulating film between conductive patterns, and the use as an etching resist film in the manufacturing of the circuit wiring. Among these, from the viewpoint that the above-described pattern has excellent resolution and has low relative permittivity, the pattern is preferably used as a protective film (permanent film) which protects the conductive pattern or as an interlayer insulating film between the conductive patterns. Examples of the conductive pattern include a wiring line of a display device, a wiring line of an imaging apparatus, a wiring line of an input device, various printed wiring lines, and a wiring line of a semiconductor package.

The above-described pattern can be used as a protective film (permanent film) which protects a conductive pattern such as an electrode pattern corresponding to a sensor in a visual recognition portion and a wiring line for a peripheral wiring portion and a lead-out wiring portion is provided inside the touch panel, or as an interlayer insulating film between conductive patterns.

### [Method for Manufacturing Touch Panel]

The method for manufacturing a touch panel according to an embodiment of the present invention is not particularly limited as long as it is a method for manufacturing a touch panel using the above-described photosensitive composition or the above-described transfer film, but it is preferable to include a step of forming a photosensitive layer on a substrate having a conductive layer (preferably, a patterned conductive layer; specifically, a touch panel electrode pattern or a conductive pattern such as a wiring line) using the photosensitive composition or the transfer film (photosensitive layer forming step), a step of exposing the photosensitive layer in a patterned manner (first exposing step), and a step of developing the exposed photosensitive layer with an alkali developer to form a protective film or an insulating film of a patterned photosensitive layer (alkali developing step).

The protective film has a function as a film which protects the surface of the conductive layer. In addition, the insulating film has a function as an interlayer insulating film between conductive layers.

In the method for manufacturing a touch panel according to the embodiment of the present invention, all of the photosensitive layer forming step, the first exposing step, and the alkali developing step can be performed by the same procedure as in the step X1, the step X2, and the step X3 of the pattern forming method of the embodiment 1 described above.

In addition, in a case where the photosensitive layer is a photosensitive layer formed from the photosensitive composition of the embodiment X-1-a3, a treatment of exposing the pattern (second exposing treatment) may be further performed before and after the development treatment. The second exposure treatment can be performed by the same procedure as in the step Y2Q of the pattern forming method of the embodiment 2 described above.

In a case where the above-described second exposure treatment is carried out, it is preferable that the method for manufacturing a touch panel according to the embodiment of the present invention further includes a step of forming a conductive layer (preferably, a patterned conductive layer; specifically, a touch panel electrode pattern or a conductive pattern such as a wiring line) on the formed insulating film.

In addition, the substrate having a conductive layer, which is used in the method for manufacturing a touch panel according to the embodiment of the present invention, is the same as the substrate having a conductive layer, which is used in the above-described step X1. Examples of other steps include the same steps as the optional step which may be included in the pattern forming methods of the first embodiment and the second embodiment.

As the method for manufacturing a touch panel according to the embodiment of the present invention, a known manufacturing method of a touch panel can be referred to for configurations other than those described above.

The touch panel manufactured by the method for manufacturing a touch panel according to the embodiment of the present invention preferably includes a transparent substrate, an electrode, and a protective film (protective layer).

As a detection method in the touch panel, any known method such as a resistive membrane system, a capacitance method, an ultrasonic method, an electromagnetic induction method, and an optical method may be used. Among these, a capacitance method is preferable.

Examples of the touch panel type include a so-called in-cell type (for example, those shown in FIGS. 5, 6, 7, and 8 of JP2012-517051A), a so-called on-cell type (for example, one described in FIG. 19 of JP2013-168125A and those described in FIGS. 1 and 5 of JP2012-089102A), an one glass solution (OGS) type, a touch-on-lens (TOL) type (for example, one described in FIG. 2 of JP2013-054727A), other configurations (for example, those described in FIG. 6 of JP2013-164871A), and various out-cell types (so-called GG, G1·G2, GFF, GF2, GF1, GIF, and the like).

### EXAMPLES

Hereinafter, the present invention will be described in more detail with reference to Examples. The material, the amount used, the proportion, the process contents, the process procedure, and the like shown in Examples can be appropriately changed, within a range not departing from the gist of the present invention. Therefore, the scope of the present invention should not be construed as being limited to Examples.

In Examples, unless otherwise specified, “part” and “%” mean “part by mass” and “% by mass”, respectively.

In addition, the meaning of each abbreviation described below is as follows.
St: styrene
AA: acrylic acid
DCPMA: dicyclopentanyl methacrylate
MAA: methacrylic acid
MMA: methyl methacrylate
BzMA: benzyl methacrylate
PGMEA: propylene glycol monomethyl ether acetate
PGME: propylene glycol monomethyl ether
MEK: methyl ethyl ketone
MFG: 1-methoxy-2-propanol

In addition, in Examples, USH-2004MB manufactured by Ushio Inc. was used as an ultra-high pressure mercury lamp, unless otherwise specified. The above-described ultra-high pressure mercury lamp has strong line spectrum at 313 nm, 365 nm, 405 nm, and 436 nm.

### Synthesis of Compound A

### [Synthesis of Polymer A1]

PGMEA (60 parts) and PGME (240 parts) were poured into a flask having a capacity of 2000 mL. The obtained liquid was heated to 90° C. while stirring at a stirring speed of 250 rpm (round per minute; the same applies hereinafter).

For preparation of a dropping liquid (1), styrene (71 parts) and acrylic acid (29 parts) were mixed and diluted with PGMEA (60 parts) to obtain the dropping liquid (1).

For preparation of a dropping liquid (2), V-601 (dimethyl 2,2′-azobis(2-methylpropionate)) (9.637 parts) was dissolved in PGMEA (136.56 parts) to obtain the dropping liquid (2).

The dropping liquid (1) and the dropping liquid (2) were simultaneously added dropwise to the above-described flask having a capacity of 2000 mL (specifically, the flask having a capacity of 2000 mL containing the liquids heated to 90° C.) over 3 hours. After the dropwise addition, V-601 (2.401 g) was added to the flask three times every hour. Thereafter, stirring was further carried out at 90° C. for 3 hours.

Thereafter, the obtained solution (reaction solution) in the above-described flask was diluted with PGMEA to obtain a solution of a polymer Al (solid content: 36.3% by mass).

### [Synthesis of Polymer A2]

PGMEA (60 parts) and PGME (240 parts) were poured into a flask having a capacity of 2000 mL. The obtained liquid was heated to 90° C. while stirring at a stirring speed of 250 rpm (round per minute; the same applies hereinafter).

For preparation of a dropping liquid (1), methyl methacrylate (40 parts), dicyclopentanyl methacrylate (40 parts), and methacrylic acid (20 parts) were mixed and diluted with PGMEA (60 parts) to obtain the dropping liquid (1).

For preparation of a dropping liquid (2), V-601 (dimethyl 2,2′-azobis(2-methylpropionate)) (9.637 parts) was dissolved in PGMEA (136.56 parts) to obtain the dropping liquid (2).

The dropping liquid (1) and the dropping liquid (2) were simultaneously added dropwise to the above-described flask having a capacity of 2000 mL (specifically, the flask having a capacity of 2000 mL containing the liquids heated to 90° C.) over 3 hours. After the dropwise addition, V-601 (2.401 g) was added to the flask three times every hour. Thereafter, stirring was further carried out at 90° C. for 3 hours.

Thereafter, the obtained solution (reaction solution) in the above-described flask was diluted with PGMEA to obtain a solution of a polymer A2 (solid content: 36.3% by mass).

### [Synthesis of Polymer A3]

A solution of a polymer A3 (solid content: 36.3% by mass) was obtained by the method according to (Synthesis of polymer A2) described above, except that MMA, DCPMA, and MAA were used as raw material monomers, and a blending ratio of each raw material monomer was changed.

### [Each Structure of Polymers A1 to A3]

Each structure of the polymers A1 to A3 are shown below.
Polymer A1: polymer in which repeating unit derived from St/repeating unit derived from AA was 71% by mass/29% by mass (Mw: 15,000)
Polymer A2: polymer in which repeating unit derived from MMA/repeating unit derived from DCPMA/repeating unit derived from MAA was 40% by mass/40% by mass/20% by mass (Mw: 20,000)
Polymer A3: polymer in which repeating unit derived from MMA/repeating unit derived from DCPMA/repeating unit derived from MAA was 30% by mass/30% by mass/40% by mass (Mw: 18,000)

### [Preparation of Photosensitive Composition]

Components shown in Table 1 were mixed according to blending amounts (part by mass) shown in the same table, and then diluted so that a blending ratio of solid content:MEK:PGMEA=36% by mass/32% by mass/32% by mass to prepare each of photosensitive compositions of Examples and Comparative Examples.

The blending amount of the compound A is intended to be the amount of the solid content of the polymer.

### Various Components

Hereinafter, each component described in Table 1 will be described.

### Compound A

Polymer A1: polymer synthesized in the above part was used.
Polymer A2: polymer synthesized in the above part was used.
Polymer A3: polymer synthesized in the above part was used.

### Compound B

9-Methylacridine: manufactured by FUJIFILM Wako Pure Chemical Corporation
Acridine: manufactured by FUJIFILM Wako Pure Chemical Corporation
9-Phenylacridine: manufactured by FUJIFILM Wako Pure Chemical Corporation

### (Molar Absorption Coefficient and Maximal Absorption Wavelength of Compound B at Wavelength of 365 nm)

Hereinafter, a procedure for measuring the molar absorption coefficient [(cm·mol/L)⁻¹] and the maximal absorption wavelength of the compound B at a wavelength of 365 nm will be described.

First, 10 mg of the compound B was weighed and added to 500 mL of acetonitrile, and the mixture was stirred at 500 rpm for 20 minutes and used as a measurement solution.

Next, an appropriate amount of the measurement solution was used, and measurement was carried out using a spectrophotometer UV-2400PC (manufactured by Shimadzu Corporation). The maximal absorption wavelength was calculated from the absorbance, and the molar absorption coefficient was calculated according to Beer-Lambert Law. At this time, as a blank, the absorbance of only acetonitrile was measured, and it was subtracted from the absorbance of the measurement solution to calculate the maximal absorption wavelength and the molar absorption coefficient of the compound B.

In a case where the compound B was insoluble in acetonitrile, the acetonitrile could be appropriately changed to a solvent for dissolving the compound B.

The molar absorption coefficient and the maximal absorption wavelength of each compound corresponding to the compound B at a wavelength of 365 nm are shown in Table 1.

### <Polymerization Initiator>

OXE-01: manufactured by BASF SE (trade name “IRGACURE OXE-02”, oxime ester-based polymerization initiator)

### Compound C

Indigo (compound having the following structure; manufactured by Tokyo Chemical Industry Co., Ltd.)

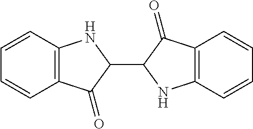 [SMILES: O=C1c2ccccc2NC1C1Nc2ccccc2C1=O]

### (Maximal Absorption Wavelength of Compound C)

The maximal absorption wavelength of the compound C was measured by the same method as that for the maximal absorption wavelength of the compound B in the section of (Molar absorption coefficient and maximal absorption wavelength of compound B at wavelength of 365 nm) described above.

The maximal absorption wavelength of each compound corresponding to the compound C is shown in Table 1.

### <Polymerizable Compound>

A-NON-N: manufactured by Shin-Nakamura Chemical Co., Ltd. (trade name “A-NON-N”, 1,9-nonanediol diacrylate)

### <Surfactant>

BYK-330: manufactured by BYK Chemie Japan (trade name “BYK-330”)

### [Various Measurements and Evaluations of Photosensitive Composition]

### [Reaction Rate of Decarboxylation Reaction]

Each of the photosensitive compositions of Examples and Comparative Examples was applied onto a silicon wafer base material such that a thickness after drying was 3.0 μm to form a coating film, and the obtained coating film was dried at 100° C. for 2 minutes to form a photosensitive layer.

Next, the photosensitive layer on the silicon wafer base material was subjected to an entire exposure using an ultra-high pressure mercury lamp under conditions such that an integrated exposure amount measured with a 365 nm wavelength illuminance meter was 1,000 mJ/cm². Next, development was performed for 35 seconds with a 1% by mass sodium carbonate aqueous solution (liquid temperature: 23° C.).

With regard to each photosensitive layer before the exposure and after the development, an infrared (IR) spectrum was measured, and a reduction rate of carboxy group was calculated from a reduction rate of a maximal absorption peak in the vicinity of 1700 cm⁻¹. The maximal absorption peak of C═O stretching and contracting of the carboxy group usually appears in a wavelength range in the vicinity of 1700 cm⁻¹.

The reduction rate of carboxy group was determined by the following expression. In the following expression, a peak height is intended to be a height of a peak top of the maximal absorption peak.

Reduction rate of carboxy group(%): {(Peak height of maximal absorption peak present in wavelength range in vicinity of 1700 cm⁻¹ in IR spectrum before exposure−Peak height of maximal absorption peak present in wavelength range in vicinity of 1700 cm⁻¹ in IR spectrum after development)/(Peak height of maximal absorption peak present in wavelength range in vicinity of 1700 cm⁻¹ in IR spectrum before exposure)}×100(%)

As the reduction rate of carboxy group is higher, the decarboxylation reaction is more proceeding.

The results were classified according to the following evaluation standard. The results are shown in Table 2.

### <Evaluation Standard>

“A”: rate of change in peak after development with respect to before exposure was 5% or more.
“B”: rate of change in peak after development with respect to before exposure was less than 5%.

### [Evaluation]

### <Evaluation of Resolution>

Each of the photosensitive compositions of Examples and Comparative Examples was applied onto a 10×10 cm² glass (EAGLE XG manufactured by Corning Incorporated) base material having a thickness of 0.1 mm such that a thickness after drying was 3.0 μm to form a coating film, and the obtained coating film was dried at 100° C. for 2 minutes to form a photosensitive layer.

Next, the photosensitive layer on the glass base material was subjected to an exposure using an ultra-high pressure mercury lamp under conditions such that an integrated exposure amount measured with a 365 nm illuminance meter was 500 mJ/cm², through a mask having a line-and-space pattern (line size of 1.0 μm and line/space of 1:1).

The exposed photosensitive layer was dip-developed with a 1% by mass sodium carbonate aqueous solution (liquid temperature: 23° C.) for 35 seconds, rinsed with pure water for 20 seconds, and then blown with air to remove water, thereby forming a pattern.

A line-and-space pattern with a line width and a space width of 1.0 um, which was produced as described above, was observed and evaluated according to the following evaluation standard. The results are shown in Table 2.

### (Evaluation Standard)

“A”: line-and-space pattern was resolved (the photosensitive layer in the space portion could be removed), and the film reduction of the pattern was 10% or less.
“B”: line-and-space pattern was resolved (the photosensitive layer in the space portion could be removed), and the film reduction of the pattern was 30% or less.
“C”: line-and-space pattern was resolved (the photosensitive layer in the space portion could be removed), and the film reduction of the pattern was 50% or less.
“D”: line-and-space pattern was not resolved (the photosensitive layer in the space portion remained, or the pattern was completely dissolved and disappeared).

### <Evaluation of Low Dielectricity>

As a test composition for dielectric constant evaluation, a composition in which the solvent component in each of the compositions of Examples and Comparative Examples was replaced with another solvent was prepared. Specifically, in each of the compositions of Examples and Comparative Examples, a test composition in which components other than solvent (solid content of photosensitive composition)/MFG/PGMEA was prepared at 36% by mass/32% by mass/32% by mass was prepared. Next, each of the test compositions of Examples and Comparative Examples was applied onto a cycloolefin (COP) base material (Arton R (R5000) of JSR Corporation) such that a thickness after drying was 5.0 μm to form a coating film, and the obtained coating film was dried at 100° C. for 20 minutes to obtain a photosensitive layer.

Next, the obtained photosensitive layer was subjected to an exposure using an ultra-high pressure mercury lamp under conditions such that an integrated exposure amount measured with a 365 nm wavelength illuminance meter is 500 mJ/cm².

A relative permittivity of the exposed photosensitive layer was measured in an environment of 25° C. and 50% RH using a 28 GHz split cylinder type resonator (manufactured by KANTO Electronic Application and Development Inc.). Specifically, the relative permittivity of the photosensitive layer was obtained by subtracting a value of a relative permittivity of the COP base material, which was measured separately according to the same conditions and method based on the value of the relative permittivity of the base material with the exposed photosensitive layer. In addition, since a film thickness distribution of the COP base material strongly affected the result, the measurement was performed at any 15 points in the plane to calculate the average value and the standard deviation. That is, each of the value of the relative permittivity of the above-described base material with the exposed photosensitive layer and the value of the relative permittivity of the above-described COP base material was measured at any 15 points in the plane, and an average value thereof was obtained.

The obtained relative permittivity at 28 GHz was classified according to the following evaluation standard. The results are shown in Table 2.

### (Evaluation Standard)

“A”: 2.9 or less
“B”: more than 2.9 and 3.2 or less
“C”: more than 3.2 and 3.5 or less
“D”: more than 3.5

Tables 1 and 2 are shown below.

Table 1 shows composition of each of the photosensitive compositions of Examples and Comparative Examples, and Table 2 shows feature portions of each of the photosensitive compositions of Examples shown in Table 1 and the measurement results and the evaluation results of each of the photosensitive compositions shown in Table 1.

In Tables 1 and 2, the “Compound A” is intended to be a compound having a carboxy group.

In Tables 1 and 2, the “Compound B” is intended to be a compound having a molar absorption coefficient of more than 1,000 (cm·mol/L)⁻¹ at a wavelength of 365 nm. In addition, the compound B is a compound having a structure in which the amount of the carboxy group included in the compound A is reduced by exposure (compound having a structure capable of accepting an electron from the carboxy group included in the compound A in a photoexcited state).

In addition, in Tables 1 and 2, the unit of “Molar absorption coefficient at wavelength of 365 nm” is (cm·mol/L)⁻¹.

In addition, in Tables 1 and 2, the “Compound C” is intended to be a compound having a maximal absorption wavelength of 580 nm to 800 nm.

In addition, in Tables 1 and 2, the “Content ratio X” is intended to be a total number (mol %) of structures capable of accepting an electron, included in the compound B, with respect to the total number of carboxy groups included in the compound A.

TABLE 1

| | Photosensitive composition | | | | | | |
|---|---|---|---|---|---|---|---|
| | | | Compound B or polymerization [symbol] | | | | |
| | Compound A | | (Comparative Example 1) | | | | |
| | | Blending | | Molar absoprtion | | Blending | |
| | | amount | | coefficient | Maximal | amount | |
| | | (part by | | at wavelength | absoprtion | (part by | Compound C |
| | Type | mass) | Type | of 365 nm | wavelength | mass) | Type |
| Example 1 | Polymer A1 | 100 | [symbol] | 6300 | 360 mm | [symbol] | — |
| Example 2 | Polymer A1 | 100 | [symbol] | 6300 | 360 mm | 10 | — |
| Example 3 | Polymer A1 | 100 | [symbol] | 6300 | 360 mm | 20 | — |
| Example 4 | Polymer A1 | 100 | [symbol] | 6300 | 360 mm | 30 | — |
| Example 5 | Polymer A1 | 100 | [symbol] | 6300 | 360 mm | 40 | — |
| Example 6 | Polymer A2 | 100 | [symbol] | 6300 | 360 mm | 10 | — |
| Example 7 | Polymer A1 | 100 | [symbol] | 6300 | 360 mm | [symbol] | — |
| Example 8 | Polymer A1 | 100 | [symbol] | 6300 | 360 mm | 10 | Indigo |
| Example 9 | Polymer A1 | 100 | [symbol] | 6300 | 360 mm | 10 | Indigo |
| Example 10 | Polymer A1 | 100 | [symbol] | 6300 | 360 mm | 10 | — |
| Example 11 | Polymer A1 | 100 | [symbol] | 6300 | 360 mm | 10 | — |
| Example 12 | Polymer A1 | 100 | [symbol] | 4900 | 360 mm | 10 | — |
| Example 13 | Polymer A1 | 100 | [symbol] | [symbol] | 360 mm | 10 | — |
| Comparative | Polymer A3 | 100 | [symbol] | 2400 | 325 nm | 4 | — |
| Example 1 | | | | | | | |

| | Photosensitive composition | | | | | |
|---|---|---|---|---|---|---|
| | | | Polymerizable compound | | | |
| | | | having [symbol] | | | |
| | Compound C | | [symbol] group | | [symbol] | |
| | | Blending | | Blending | | Blending |
| | Maximal | amount | | amount | | amount |
| | absoprtion | (part by | | (part by | | (part by |
| | wavelength | mass) | Type | mass) | Type | mass) |
| Example 1 | — | 0 | — | 0 | BYK330 | 0.2 |
| Example 2 | — | 0 | — | 0 | BYK330 | 0.2 |
| Example 3 | — | 0 | — | 0 | BYK330 | 0.2 |
| Example 4 | — | 0 | — | 0 | BYK330 | 0.2 |
| Example 5 | — | 0 | — | 0 | BYK330 | 0.2 |
| Example 6 | — | 0 | — | 0 | BYK330 | 0.2 |
| Example 7 | — | 0 | — | 0 | BYK330 | 0.2 |
| Example 8 | 603 mm | 10 | — | 0 | BYK330 | 0.2 |
| Example 9 | 603 mm | [symbol] | — | 0 | BYK330 | 0.2 |
| Example 10 | — | 0 | A-NOD-N | 60 | BYK330 | 0.2 |
| Example 11 | — | 0 | A-NOD-N | 1 | BYK330 | 0.2 |
| Example 12 | — | 0 | — | 0 | BYK330 | 0.2 |
| Example 13 | — | 0 | — | 0 | BYK330 | 0.2 |
| Comparative | — | 0 | A-NOD-N | [symbol] | BYK330 | 0.2 |
| Example 1 | | | | | | |

[symbol]

indicates data missing or illegible when filed

TABLE 2

| | Part of feature portion of each photosensitive | | | | Evaluation | |
|---|---|---|---|---|---|---|
| | composition of Examples in Table 1 | | | | | Low |
| | Content of | Content of polymerizable | | | | dielectricity |
| | compound C with | compound having ethylenically | Content | Reaction rate of | | (relative |
| | respect to compound | unsaturated group with respect to | ratio X | decarboxylation | Resolution | permittivity |
| | A (% by mass) | total solid content (% by mass) | (mol %) | reaction | (L/S = 1/1) | at 28 GHz) |
| Example 1 | — | — | 6.4 | A | B | C |
| Example 2 | — | — | 12.9 | A | A | A |
| Example 3 | — | — | 25.7 | A | A | A |
| Example 4 | — | — | 38.6 | A | A | A |
| Example 5 | — | — | 51.4 | A | A | A |
| Example 6 | — | — | 22.3 | A | A | A |
| Example 7 | — | — | 70.7 | A | B | B |
| Example 8 | 10 | — | 12.9 | A | C | C |
| Example 9 | 3 | — | 12.9 | A | B | B |
| Example 10 | — | 35 | 12.9 | A | C | B |
| Example 11 | — | 0.9 | 12.9 | A | B | A |
| Example 12 | — | — | 13.9 | A | A | A |
| Example 13 | — | — | 9.7 | A | A | A |
| Comparative | — | — | — | B | D | D |
| Example 1 | | | | | | |

From the results of Tables 1 and 2, it was found that, in a case where the photosensitive compositions of Examples were exposed to irradiation light including light having a wavelength of 365 nm, the resolution was excellent and the low dielectricity of the formed pattern was excellent (in other words, dielectricity was further lowered).

In addition, from the comparison between Examples 1 to 5 and 7, it was found that, in a case where the content of the compound B was 10 to 50 parts by mass with respect to 100 parts by mass of the content of the compound A, in the exposure by the irradiation light including light having a wavelength of 365 nm, the resolution was more excellent and the low dielectricity of the formed pattern was more excellent.

From the comparison between Examples 2, 8, and 9, it was found that, in a case where the content (% by mass) of the compound C with respect to the compound A was less than 3% by mass, in the exposure by the irradiation light including light having a wavelength of 365 nm, the resolution was more excellent and the low dielectricity of the formed pattern was more excellent.

From the comparison between Examples 2, 10, and 11, it was found that, in a case where the content of the polymerizable compound having an ethylenically unsaturated group was 30% by mass or less (preferably, 0.5% by mass or less) with respect to the total solid content of the composition, in the exposure by the irradiation light including light having a wavelength of 365 nm, the resolution was more excellent and the low dielectricity of the formed pattern was more excellent.

### Other Evaluations

### (Pattern Formability 1 in Form of Transfer Film)

A photosensitive layer having a thickness of 3.0 μm was formed on a temporary support (PET film manufactured by Toray Industries, Inc., LUMIRROR 16FB40, thickness: 16 μm) using each of the photosensitive compositions of Examples shown in Table 1. The photosensitive layer was formed by applying and drying the photosensitive composition. Next, a cover film (manufactured by Oji F-Tex Co., Ltd., polypropylene film, FG-201, thickness: 30 μm) was provided on the photosensitive layer to obtain a transfer film.

The transfer film was laminated on a base material (10×10 cm² glass (EAGLE XG manufactured by Corning Incorporated) having a thickness of 0.1 mm). Specifically, the cover film was peeled off from the transfer film, and the transfer film was laminated so that a surface exposed by peeling off the cover film faced the above-described base material, thereby obtaining a laminate. Laminating conditions were conditions in which a temperature of the base material was 40° C., a temperature of a rubber roller was 110° C., a linear pressure was 3 N/cm, and a transportation speed was 2 m/min.

After peeling off the temporary support from the obtained laminate, the photosensitive layer was exposed using an ultra-high pressure mercury lamp under conditions such that an integrated exposure amount measured with a 365 nm illuminance meter was 500 mJ/cm², through a mask having a line size of 1.0 μm and a line:space=1:1.

Next, the exposed laminate was developed for 35 seconds using a 1% by mass sodium carbonate aqueous solution (liquid temperature: 23° C.) as a developer. After the development, the laminate was rinsed with pure water for 20 seconds, and then air was blown to remove water, thereby producing a pattern.

In a case where the pattern produced in this way was observed and classified based on the evaluation standard described in <Evaluation of resolution> described above, it was the same as the evaluation result of the upper part (in order words, the evaluation result of Examples in which the photosensitive layer was formed by directly applying the photosensitive composition onto the base material).

### (Pattern Formability 2 in Form of Transfer Film—Evaluation at Each Film Thickness)

<<Pattern Formability in Photosensitive Layer Having Thickness of 3.0 μm>>

A photosensitive layer having a thickness of 3.0 μm was formed on a temporary support (PET film manufactured by Toray Industries, Inc., LUMIRROR 16KS40, thickness: 16 μm) using each of the photosensitive compositions of Examples shown in Table 1. A photosensitive layer having a thickness of 3.0 μm was formed of each of the compositions of Examples. The photosensitive layer was formed by applying and drying the photosensitive composition. Next, a cover film (manufactured by Oji F-Tex Co., Ltd., polypropylene film, E-201F, thickness: 30 μm) was provided on the photosensitive layer to obtain a transfer film.

The transfer film was laminated on a base material (COP base material (thickness: 30 μm) having an ITO transparent electrode having a thickness of 50 nm on a surface). Specifically, the cover film was peeled off from the transfer film, and the transfer film was laminated so that a surface exposed by peeling off the cover film faced the above-described base material, thereby obtaining a laminate. Laminating conditions were conditions in which a temperature of the base material was 40° C., a temperature of a rubber roller was 110° C., a linear pressure was 3 N/cm, and a transportation speed was 2 m/min.

After peeling off the temporary support from the obtained laminate, the photosensitive layer was exposed using an ultra-high pressure mercury lamp under conditions such that an integrated exposure amount measured with a 365 nm illuminance meter was 500 mJ/cm², through a mask having a line size of 9.0 μm and a line:space=1:1.

Next, the exposed laminate was developed for 35 seconds using a 1.0% by mass sodium carbonate aqueous solution (liquid temperature: 26° C.) as a developer. After the development, the laminate was rinsed with pure water for 20 seconds, and then air was blown to remove water, thereby producing a pattern.

In a case where the obtained pattern was observed, it was confirmed that the line-and-space pattern was finely formed.

<<Pattern Formability in Photosensitive Layer Having Thickness of 5.5 μm or 8.0 μm>>

In addition, a pattern was formed according to the same procedure as in <<Pattern formability in photosensitive layer having thickness of 3.0 μm>> described above, except that, at the time of producing the transfer film, the film thickness of the photosensitive layer was set to 5.5 μm or 8.0 μm.

In a case where the obtained pattern was observed, it was confirmed that the line-and-space pattern was finely formed.

### (Pattern Formability 3 in Form of Photosensitive Composition—Evaluation at Each Film Thickness)

<<Pattern Formability in Photosensitive Layer Having Thickness of 0.9 μm>>

Each of the photosensitive compositions of Examples was applied onto a 10×10 cm² glass (EAGLE XG manufactured by Corning Incorporated) base material having a thickness of 0.1 mm such that a thickness after drying was 0.9 μm to form a coating film, and the obtained coating film was dried at 100° C. for 2 minutes to form a photosensitive layer.

Next, the photosensitive layer on the glass base material was subjected to an exposure using an ultra-high pressure mercury lamp under conditions such that an integrated exposure amount measured with a 365 nm illuminance meter was 500 mJ/cm², through a mask having a line-and-space pattern (line size of 5.0 μm and line/space of 1:1).

The exposed photosensitive layer was dip-developed with a 1% by mass sodium carbonate aqueous solution (liquid temperature: 26° C.) for 35 seconds, rinsed with pure water for 20 seconds, and then blown with air to remove water, thereby forming a pattern.

In a case where the obtained pattern was observed, it was confirmed that the line-and-space pattern was finely formed.

<<Pattern Formability in Photosensitive Layer Having Thickness of 1.5 μm or 2.0 μm>>

In addition, a pattern was formed according to the same procedure as in <<Pattern formability in photosensitive layer having thickness of 0.9 μm>> described above, except that the film thickness of the photosensitive layer was set to 1.5 μm or 2.0 μm.

In a case where the obtained pattern was observed, it was confirmed that the line-and-space pattern was finely formed.

### EXPLANATION OF REFERENCES

12: temporary support
14: photosensitive layer
16: cover film
100: transfer film

What is claimed is:

1. A photosensitive composition comprising:
a compound A having a carboxy group; and
a compound B having a molar absorption coefficient at a wavelength of 365 nm of more than 1,000 (cm·mol/L)⁻¹,
wherein a content of the carboxy group is reduced by irradiation with an actinic ray or a radiation.

2. The photosensitive composition according to claim 1,
wherein the molar absorption coefficient of the compound B at the wavelength of 365 nm is 3,000 (cm·mol/L)⁻¹ or more.

3. The photosensitive composition according to claim 1,
wherein a maximal absorption wavelength of the compound B is in a range of 300 to 400 nm.

4. The photosensitive composition according to claim 1,
wherein the compound B is a compound having a structure in which an amount of the carboxy group included in the compound A is reduced by an exposure.

5. The photosensitive composition according to claim 4,
wherein the compound B is a compound having a structure capable of accepting an electron from the carboxy group included in the compound A in a photoexcited state.

6. The photosensitive composition according to claim 3,
wherein the compound B is a compound having a structure capable of accepting an electron from the carboxy group included in the compound A in a photoexcited state, and
a total number of the structures capable of accepting the electron, which are included in the compound B, is 5 mol % or more with respect to a total number of carboxy groups included in the compound A.

7. The photosensitive composition according to claim 1,
wherein the compound B is an aromatic compound which may have a substituent.

8. The photosensitive composition according to claim 1,
wherein the compound B is a polycyclic aromatic ring compound which may have a substituent.

9. The photosensitive composition according to claim 1,
wherein the photosensitive composition contains no compound C having a maximal absorption wavelength of 580 to 800 nm, or
in a case of containing the compound C, a content of the compound C is less than 10% by mass with respect to a content of the compound A.

10. The photosensitive composition according to claim 1,
wherein the compound A is a polymer including one or more selected from the group consisting of a repeating unit derived from acrylic acid and a repeating unit derived from methacrylic acid.

11. The photosensitive composition according to claim 1,
wherein the photosensitive composition contains no polymerizable compound having an ethylenically unsaturated group, or
in a case of containing the polymerizable compound, a content of the polymerizable compound is 30% by mass or less with respect to a total solid content of the composition.

12. The photosensitive composition according to claim 1,
wherein the photosensitive composition contains no polymerizable compound having an ethylenically unsaturated group, or
in a case of containing the polymerizable compound, a content of the polymerizable compound is 0.5% by mass or less with respect to a total solid content of the composition.

13. The photosensitive composition according to claim 12,
wherein the compound A is a carboxy group-containing polymer having a repeating unit represented by General Formula (A): 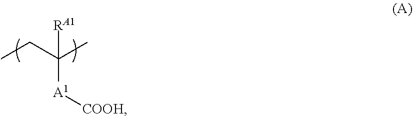
and
the compound B is a polycyclic aromatic ring compound including an acridine ring.

14. The photosensitive composition according to claim 1,
wherein a content of the compound B is more than 0 parts by mass and 50 parts by mass or less with respect to 100 parts by mass of a content of the compound A.

15. The photosensitive composition according to claim 1,
wherein a content of the compound B is 10 to 50 parts by mass with respect to 100 parts by mass of a content of the compound A.

16. The photosensitive composition according to claim 1,
wherein the compound A is a carboxy group-containing polymer having a repeating unit represented by General Formula (A): 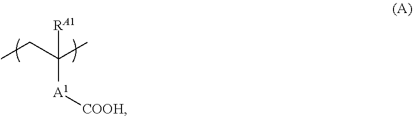
the compound B is a compound having a structure capable of accepting an electron from the carboxy group included in the compound A in a photoexcited state, and
a total number of the structures capable of accepting the electron, which are included in the compound B, is 10 mol % or more with respect to a total number of carboxy groups included in the compound A.

17. The photosensitive composition according to claim 1,
wherein, in a case where the following pattern forming method A is performed on a photosensitive layer formed from the photosensitive composition to form a pattern, a film reduction amount represented by Expression (F1) is 50% or less, and
in a case where the following film forming method B is performed on the photosensitive layer formed from the photosensitive composition to form a film, a relative permittivity of the film at 28 GHz, which is measured in an environment of 25° C. and 50% RH, is 3.5 or less,
film reduction amount (%)={(thickness of photosensitive layer before exposure−thickness of protruding portion of formed pattern)/thickness of photosensitive layer before exposure}×100 Expression (F1):
<<pattern forming method A>>
the photosensitive composition is applied onto a base material such that a thickness after drying is 3.0 μm to form a coating film, the obtained coating film is dried at 100° C. for 2 minutes to form a photosensitive layer, the photosensitive layer is exposed using an ultra-high pressure mercury lamp under conditions such that an integrated exposure amount measured with a 365 nm wavelength illuminance meter is 500 mJ/cm², through a mask having a line-and-space pattern with a line size of 1 μm and a line/space of 1/1, and the exposed photosensitive layer is developed by being immersed in a 1% by mass sodium carbonate aqueous solution at a liquid temperature of 23° C. for 35 seconds, rinsed with pure water for 20 seconds, and then blown with air to remove water,
<<film forming method B>>
the photosensitive composition is applied onto a base material such that a thickness after drying is 5.0 μm to form a coating film, the obtained coating film is dried at 100° C. for 2 minutes to form a photosensitive layer, and the photosensitive layer is exposed using an ultra-high pressure mercury lamp under conditions such that an integrated exposure amount measured with a 365 nm wavelength illuminance meter is 500 mJ/cm².
